(19) United States
(12) Patent Application Publication
(10) Pub. No.: US 2025/0119106 A1
(43) Pub. Date: Apr. 10, 2025

(54) METHODS AND APPARATUS TO REDUCE MISMATCHES BETWEEN DIFFERENTIAL PAIRS OF SIGNALS

(71) Applicant: Texas Instruments Incorporated, Dallas, TX (US)

(72) Inventors: Tanmay Halder, Bangalore (IN); Anand Subramanian, Bangalore (IN); Laxmi Vivek Tripurari, Bangalore (IN); Anand Kannan, Bangalore (IN)

(21) Appl. No.: 18/525,324

(22) Filed: Nov. 30, 2023

(30) Foreign Application Priority Data
Oct. 4, 2023 (IN) 202341066376

(51) Int. Cl. H03F 1/56; H03F 3/45

(52) U.S. Cl. CPC H03F 1/56; H03F 3/45071; H03F 2200/03; H03F 2203/45181

(57) ABSTRACT

An example apparatus includes: voltage divider circuitry configured to determine a common mode voltage of a differential pair of signals having a first voltage and a second voltage; a first amplifier coupled to the voltage divider circuitry, the first amplifier configured to determine a difference between the common mode voltage and a reference common mode voltage; current compensation circuitry coupled to the first amplifier, the current compensation circuitry configured to generate a first current and a second current responsive to the difference between voltages; and a second amplifier coupled to the voltage divider circuitry and the current compensation circuitry, the second amplifier to compensate the first voltage with the first current and the second voltage with the second current.

### CROSS-REFERENCE TO RELATED APPLICATION

This patent application claims the benefit of and priority to IN Provisional Patent Application No. 202341066376 filed Oct. 4, 2023, which is hereby incorporated herein by reference in its entirety.

### TECHNICAL FIELD

This description relates generally to mismatches in circuitry and, more particularly, to methods and apparatus to reduce mismatches between differential pairs of signals.

### BACKGROUND

With continuing advancements in electronic design, analog-to-digital converters (ADCs) and digital-to-analog converters (DACs) have become capable of operating at increasing speed, precision, and power efficiency. Both ADCs and DACs utilize amplifiers to interface with analog signals, such as analog inputs of an ADC and analog outputs of a DAC. Using differential pairs of signals as a method of noise management continues to become increasingly popular. Partially and/or fully differential ADCs and DACs are becoming increasingly popular due to their noise management advantages. Designers have been developing ADCs and DACs that use fully differential amplifiers or a plurality of amplifiers to interface with analog signals and accommodate use of differential pairs of analog signals.

### SUMMARY

For methods and apparatus to reduce mismatches between a differential pair of signals, an example apparatus includes voltage divider circuitry configured to determine a common mode voltage of a differential pair of signals having a first voltage and a second voltage; a first amplifier coupled to the voltage divider circuitry, the first amplifier configured to determine a difference between the common mode voltage and a reference common mode voltage; current compensation circuitry coupled to the first amplifier, the current compensation circuitry configured to generate a first current and a second current responsive to the difference between voltages; and a second amplifier coupled to the voltage divider circuitry and the current compensation circuitry, the second amplifier to compensate the first voltage with the first current and the second voltage with the second current.

### BRIEF DESCRIPTION OF THE DRAWINGS

FIG. 1 is a block diagram of an example audio device including an analog-to-digital converter (ADC) and a digital-to-analog converter (DAC) having mismatch compensation circuitry to correct mismatch between signals of a differential signal.

FIG. 2 is a schematic diagram of an example of the ADC of FIG. 1 including the mismatch compensation circuitry of FIG. 1.

FIG. 3 is a schematic diagram of an example of the mismatch compensation circuitry of FIGS. 1 and 2.

FIG. 4 is a schematic diagram of an example of the DAC of FIG. 1 including the mismatch compensation circuitry of FIGS. 1-3.

FIG. 5 is a schematic diagram of another example of the DAC of FIG. 1 including the mismatch compensation circuitry of FIGS. 1-3 and circuitry to convert a differential signal to a single ended signal.

FIG. 6 is a schematic diagram of yet another example of the DAC of FIG. 1 including another example of the mismatch compensation circuitry of FIGS. 1-5 and single-ended driver circuitry to supply a differential signal as an output.

FIG. 7 is a plot of example operations of the DAC of FIGS. 1 and 4 with and without the mismatch compensation circuitry of FIGS. 1-6.

FIG. 8 is a flowchart representative of example operations that may be executed, instantiated, and/or performed using an example implementation of the mismatch compensation circuitry of FIGS. 1-6.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. Although the drawings show regions with clean lines and boundaries, some or all of these lines and/or boundaries may be idealized. In reality, the boundaries and/or lines may be unobservable, blended and/or irregular.

With continuing advancements in electronic design, analog-to-digital converters (ADCs) and digital-to-analog converters (DACs) have become capable of operating at increasing speed, precision, and power efficiency. Both ADCs and DACs utilize amplifiers to interface with analog signals, such as analog inputs of an ADC and analog outputs of a DAC. Using differential pairs of signals as a method of noise management continues to become increasingly popular. Partially and/or fully differential ADCs and DACs are becoming increasingly popular due to their noise management advantages. Designers have been developing ADCs and DACs that use fully differential amplifiers or a plurality of amplifiers to interface with analog signals and accommodate use of differential pairs of analog signals.

Some devices, such as audio devices, rely on an ADC, a DAC, or both. In some such devices, the ADC may be coupled to an analog audio source (e.g., a microphone, receiver, etc.), which supplies a differential pair of analog input signals representing audio information. Ideally, the ADC converts one or more approximately equal-amplitude analog input signals into one or more digital output signals for signal processing, storage, playback, etc. One example ADC, a delta-sigma ADC, utilizes loop filter circuitry to convert analog signal(s) into digital signal(s). The delta-sigma ADC uses a plurality of unit elements of one or more DACs and oversampling to perform the analog-to-digital conversion using feedback. The delta-sigma ADC combines the output of the DACs with the analog signals to generate additional bits of the digital output. In such ADCs, mismatches between unit elements and/or feedback circuitry of the delta-sigma ADC result in a formation of asymmetries. Such asymmetries increase with each feedback cycle of the delta-sigma ADC.

In some examples, signals of differential analog signals may vary in amplitude from one another responsive to mismatch between components of the analog audio source or the feedback circuitry of the delta-sigma ADC. For example, a first analog signal of a differential pair of signals may have a first amplitude greater than a second amplitude of a second analog signal of the differential pair of signals. As explained above, ideally, the first and second amplitudes are approximately equal. However, component mismatch results in asymmetries between signals of the differential pair of signals.

In other devices, the DAC may be coupled between a digital audio source and analog audio playback circuitry (e.g., a speaker, amplifier, etc.). The DAC receives one or more digital input signals and converts the digital signals into an analog output signal(s). Driver circuitry generates audio responsive to the analog output signal(s) from the DAC. One such example of a DAC is a class B DAC, which utilizes a delta-sigma modulator and tri-level unit cells to convert the digital input signal(s) into the differential pair of analog output signals. The class B DAC uses a delta-sigma modulator and a plurality of unit cells to generate a differential pair of output currents representing the digital input signal(s). The class B DAC uses current-to-voltage (I-V) converter circuitry as driver circuitry which generates the analog output signal(s) responsive to the differential pair of output currents.

However, signals of the differential pair of analog output signals from the DAC may vary from one another responsive to mismatch between components of the unit cells or the I-V converter circuitry of the class B DAC. For example, a first current of the differential pair of output currents may have a first amplitude which differs from a second amplitude of a second current of the differential pair of output currents. In such examples, ideally, the first and second amplitudes are approximately equal, however component mismatch of the unit cells result in asymmetries between current of the differential pair of output currents. Further, asymmetries of the differential pair of analog output signals may be responsive to mismatches between feedback components of the I-V converter circuitry. For example, asymmetries of signals of the differential pair of analog output signals may be responsive to manufacturing tolerances of feedback resistors of the I-V converter circuitry.

In both ADC and DAC examples, asymmetries between signals of the differential pair of analog signals increases total harmonic distortion (THD). THD represents a distortion due to harmonics at different frequencies of the differential pair of analog signals. Signals with relatively high THDs have relatively high voltages at harmonic frequencies. Signals having relatively high THDs result in audible distortions. Asymmetries between signals of the differential pair of analog signals increase the THD.

One method to reduce asymmetries, and attendant THD, between signals of the differential pair of analog signals is to use relatively higher area components, which limits mismatches to relatively smaller tolerances. For example, a five percent tolerance of a ten-ohm (Ω) resistor has substantially less variation (i.e., +/−0.5 ohms) in comparison to a five percent tolerance of a one-thousand-ohm resistor (i.e., +/−50 ohms). However, reducing values of components to reduce variations in component values arising from manufacturing tolerances limits performance of ADCs and DACs. For example, variations in component values resulting from tolerances increases THD.

Another method of reducing asymmetries and resulting THD between signals of the differential pair of analog signals is trimming, or adjusting, component values to reduce mismatch. For example, during manufacturing, setting trim codes of components such that a resistance of a first resistor is approximately the same value as a resistance of a second resistor. However, trimming values of the components is limited to the precision of the trim codes. Also, the component values may vary across a range of temperatures. In such examples, the accuracy of the trim codes may vary at different temperatures.

Yet another method of reducing asymmetry between signals of a differential pair of signals is to include chopping circuitry to chop feedback components. For example, the chopping circuitry may include a plurality of switches coupled to the output of the I-V converter circuitry. In such examples, the switches limit the THD by switching between components. However, charge injection and clock feedthrough on the analog output signals are responsive to switching of the chopping circuitry. Also, using the chopping circuitry for components is limited to resistor-based DACs, which does not include class B DACs, and may have data dependent glitches which results in increases in harmonic distortion.

Examples described herein include methods and apparatus to reduce mismatches between a differential pair of signals using mismatch compensation circuitry. In some described examples, the mismatch compensation circuitry generates plus and minus side compensation currents to compensate a differential pair of analog signals for asymmetries. In some such examples, the mismatch compensation circuitry includes common mode determination circuitry, an error amplifier, and current compensation circuitry. The common mode determination circuitry determines a common mode voltage between signals of the differential pair of analog signals. The error amplifier determines the difference between the common mode voltage and a reference common mode voltage. The reference common mode voltage may be referred to as a target or reference voltage. The current compensation circuitry converts the determined difference into first and second compensation currents. In some examples, the current compensation circuitry generates plus and minus side compensation currents by switching between the first and second compensation currents.

The mismatch compensation circuitry supplies the plus side compensation current to compensate a first one of the differential pair of analog signals for mismatches resulting in asymmetries. Also, the mismatch compensation circuitry supplies the minus side compensation current to compensate a second one of the differential pair of analog signals for mismatches resulting in asymmetries. Advantageously, the mismatch compensation circuitry reduces asymmetries between signals of a differential pair of signals using the plus and minus side compensation currents. Advantageously, the mismatch compensation circuitry reduces harmonic distortions responsive to compensating signals of the differential pair of signals with the plus and minus side compensation currents.

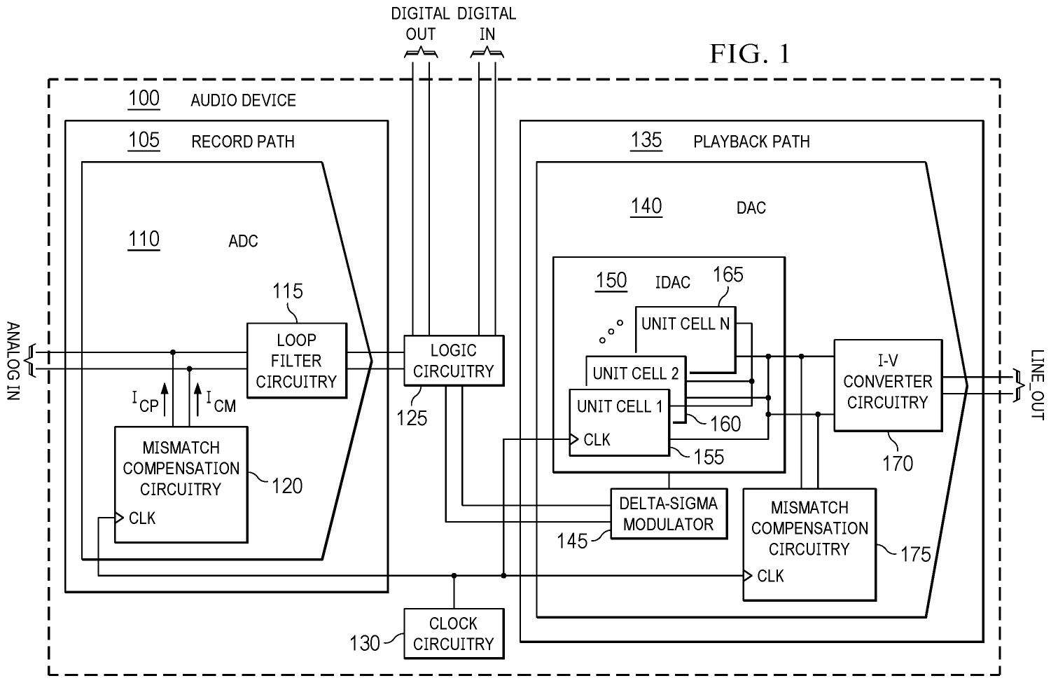

FIG. 1 is a block diagram of an example audio device 100. In the example of FIG. 1, the audio device 100 includes example record path circuitry 105, example logic circuitry 125, example clock circuitry 130, and example playback path circuitry 135. Record path circuitry 105 includes an example ADC 110, which includes example loop filter circuitry 115 and first example mismatch compensation circuitry 120. Example playback circuitry 135 includes an example DAC 140, which includes an example delta-sigma modulator (DSM) circuitry 145, an example current digital-to-analog converter (IDAC) 150, example I-V converter (driver) circuitry 170, and second example mismatch compensation circuitry 175. The IDAC 150 includes N number of unit cells, where N is a positive integer. As shown, the IDAC 150 includes a first example unit cell circuitry 155, a second example unit cell circuitry 160, and a third example unit cell circuitry 165.

The record path circuitry 105 is coupled to the logic circuitry 125 and the clock circuitry 130 and may be coupled to external audio source circuitry. In some examples, the external audio source circuitry is transducer circuitry, such as a microphone. In an example, the record path circuitry 105 receives analog input signals (ANALOG IN) from the external audio source circuitry. For instance, analog input signals include a differential pair of analog input signals, which represent audio data. Alternatively, the input signal is a single-ended signal representing audio data. The record path circuitry 105 converts the analog input signals to digital output signals representing the audio data. The digital output signals are referred to as a digital signal, which represent the audio data. The record path circuitry 105 supplies the digital output signals to the logic circuitry 125. In some examples, the record path circuitry 105 may include additional circuitry to perform additional operations to data of the digital output signals, such as filtering, processing, conditioning, etc.

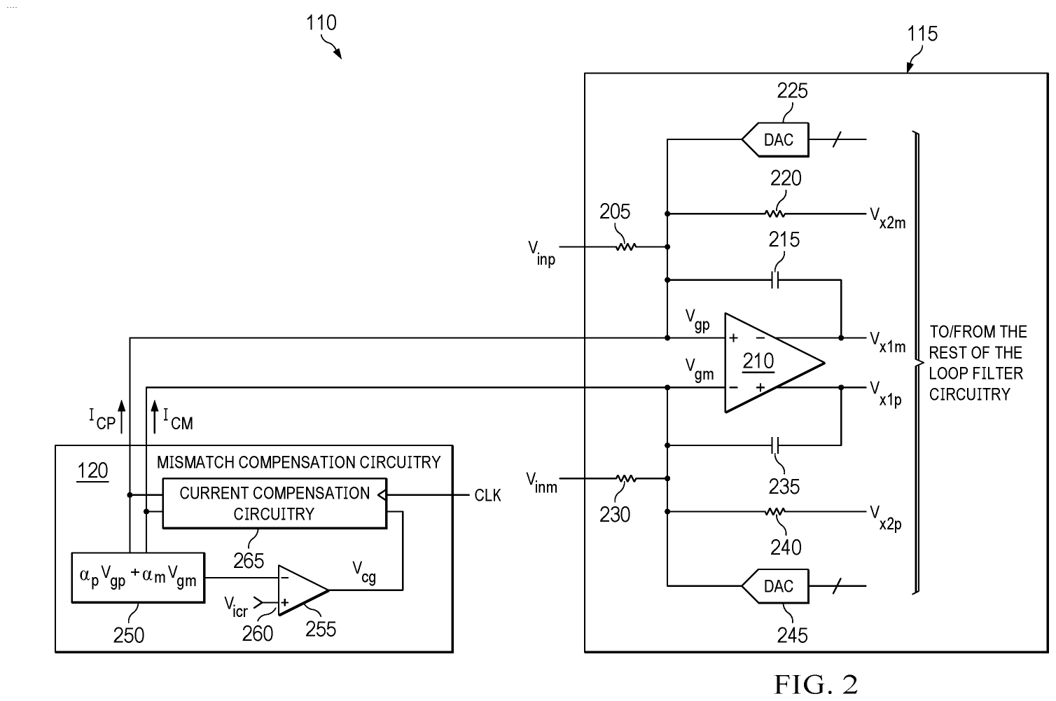

The ADC 110 has first and second inputs that may be coupled to the external audio source circuitry, which supplies the differential pair of analog input signals, and a clock input coupled to the clock circuitry 130. The ADC 110 has first and second outputs coupled to the logic circuitry 125. The ADC 110 receives the differential pair (/single-ended) of analog input signals from the external audio source circuitry. The ADC 110 converts the differential pair (/single-ended) of analog input signals into the digital output signals. In some examples, the ADC 110 is a delta-sigma ADC, which utilizes the loop filter circuitry 115 and one or more single bit DACs as a delta-sigma modulator. Such an example is illustrated in FIG. 2 and described further below. The ADC 110 supplies the digital output signals to the logic circuitry 125.

The loop filter circuitry 115 has first and second inputs coupled to the first mismatch compensation circuitry 120 and that may be coupled to the external audio source circuitry, which supplies the analog input signals. The loop filter circuitry 115 has first and second outputs coupled to the logic circuitry 125. The loop filter circuitry 115 receives the differential pair of analog input signals from the external audio source circuitry. The loop filter circuitry 115 receives plus and minus side compensation currents from the first mismatch compensation circuitry 120. The plus and minus side compensation currents adjust a common mode voltage of the differential pair of analog input signals to reduce asymmetries between signals of the differential pair of analog input signals. The plus and minus side compensation currents are further described in connection with the mismatch compensation circuitry 120, 175, below, and FIGS. 2-6. The loop filter circuitry 115 combines currents of the differential pair of analog input signals and the plus and minus compensation currents at the first and second inputs of the loop filter circuitry 115. The loop filter circuitry 115 uses the combined currents and feedback circuitry (illustrated in FIG. 2) to generate the digital output signals.

Advantageously, the compensation currents reduce asymmetries between signals of the differential pair of analog input signals by modifying the common mode voltage of the differential pair of analog input signals at the first and second inputs of the loop filter circuitry 115. Advantageously, magnitudes of the compensation currents may be adjusted so the common mode voltage of the differential pair of analog input signals is approximately the mid-point at a given time. Advantageously, the compensation currents modify signals of the differential pair of analog input signals to compensate for mismatches and asymmetries.

The first mismatch compensation circuitry 120 has first and second terminals coupled to the loop filter circuitry 115 and that may be coupled to the external audio source circuitry, which supplies the differential pair of analog input signals. In some examples, the first mismatch compensation circuitry 120 has a third terminal coupled to the clock circuitry 130. The first mismatch compensation circuitry 120 receives the differential pair of analog input signals from the external circuitry.

The first mismatch compensation circuitry 120 determines a common mode voltage of the differential pair of analog input signals. In some examples, the first mismatch compensation circuitry 120 determines the common mode voltage of the differential pair of analog input signals as a midpoint voltage between signals of the differential pair of analog input signals. In such examples, the first mismatch compensation circuitry 120 determines the midpoint voltage by dividing the voltage difference between the signals of the differential pair of analog input signals by two and in reference to a voltage of one of the signals. For example, when a first one of the differential pair of analog input signals is four volts (V), and a second one of the differential pair of analog input signals is negative two volts, the first mismatch compensation circuitry 120 determines the common mode voltage to be approximately one volt.

The first mismatch compensation circuitry 120 determines a difference between the common mode voltage and a reference common mode voltage. In an example, the common mode voltage is approximately one volt, and the reference common mode voltage is zero volts (e.g., a common potential, ground, etc.). In this example, the first mismatch compensation circuitry 120 determines the difference to be approximately one volt. In some examples, the first mismatch compensation circuitry 120 amplifies the determined difference between common mode voltages by a gain. In such examples, the gain of the first mismatch compensation circuitry 120 may be relatively high so the compensation currents are capable of compensating relatively high-power signals. The first mismatch compensation circuitry 120 generates the plus and minus side compensation currents responsive to differences between the common mode voltage and the reference common mode voltage. For example, when the difference is a first value, a magnitude of the compensation currents is a first value, and when the difference is a second value, the magnitude of the compensation currents is a second value.

The first mismatch compensation circuitry 120 supplies a plus side compensation current (I_{CP}) to the first input of the loop filter circuitry 115 and a minus side compensation current (I_{CM}) to the second input of the loop filter circuitry 115. The plus and minus compensation currents are approximately equal. In some examples, the first mismatch compensation circuitry 120 switches which of the inputs of the loop filter circuitry 115 that sources of the plus and minus side compensation currents are supplied to. For example, the first mismatch compensation circuitry 120 supplies a first compensation current to the first input of the loop filter circuitry 115 as the plus side compensation current and a second compensation current to the second input of the loop filter circuitry 115 as the minus side compensation current, for a first portion of a clock cycle. In such examples, the first mismatch compensation circuitry 120 supplies the first compensation current to the second input of the loop filter circuitry 115 as the minus side compensation current and the second compensation current to the first input of the loop filter circuitry 115 as the plus side compensation current, for a second portion of the clock cycle. Advantageously, the first mismatch compensation circuitry 120 may switch the supply of the compensation currents between signals of the differential pair of analog input signals to account for component, process, environment mismatch between generation of each the compensation currents.

The logic circuitry 125 has first inputs coupled to the loop filter circuitry 115 and second inputs that may be coupled to an external digital audio source, which supplies digital input signals. The digital input signals represent audio data. The logic circuitry 125 has first outputs that may be coupled to an external digital audio receiver, which receives the digital output signals. The logic circuitry 125 receives the digital output signals from the loop filter circuitry 115. The logic circuitry 125 may process data of the digital output signals to perform one or more audio operations. For example, the logic circuitry 125 modifies data of the digital output signals to perform audio operations such as volume control, frequency equalizing, psycho-acoustic bass filter, dynamic range correction, rattle noise suppression, etc. The logic circuitry 125 supplies the digital output signals to the playback path circuitry 135 and/or the external digital audio receiver. In some examples, an external speaker (not shown) generates audible sound responsive to the logic circuitry 125 supplying the digital output signals to the playback path circuitry 135. In such examples, the audible sound corresponds to the digital output signals from the logic circuitry 125. In other examples, the logic circuitry 125 supplies the digital output signals to the external digital receiver circuitry to playback the audio signal at a later time or using an alternative medium, such as streaming.

The clock circuitry 130 is coupled to the mismatch compensation circuitry 120, 175 and the unit cells 155, 160, 165. The clock circuitry 130 generates a clock signal (CLK) of having an operating frequency. The operating frequency defines a duration of a clock cycle, which includes a first duration where the clock signal is a logic high and a second duration where the clock signal is a logic low. The operating frequency may set or affect the speed of the ADC 110 and/or the DAC 140. For example, a rising edge of each cycle of the clock signal indicates a bit of data, and the frequency represents a data rate of the digital signals. In some examples, the clock circuitry 130 is or includes external crystal oscillator (XTAL) circuitry. In such examples, the clock circuitry 130 is external to the audio device 100. The clock circuitry 130 supplies the clock signal to the mismatch compensation circuitry 120, 175 and the unit cells 155, 160, 165.

The playback path circuitry 135 is coupled to the logic circuitry 125 and the clock circuitry 130 and that may be coupled to external audio circuitry. In some examples, the external audio circuitry is a transducer, such as a speaker. In other examples, the external audio circuitry is an audio amplifier, receiver, etc. The playback path circuitry 135 receives digital input signals from the logic circuitry 125. The digital input signals represent audio data. In some examples, the digital input signals are approximately equal to the digital output signal(s) from the record path circuitry 105. In other examples, the digital input signal(s) are approximately equal to signals supplied by an external digital audio source coupled to the logic circuitry 125. In both examples, the logic circuitry 125 modifies the digital signals to perform one or more audio operations before supplying the digital input signals to the playback path circuitry 135.

The playback path circuitry 135 converts the digital input signals to a differential pair of analog output signals (LINE_OUT) representing the audio data of the digital input signals. The differential pair of analog output signals represent the audio data. The playback path circuitry 135 supplies the differential pair of analog output signals to the external audio circuitry, which generates audible sound. In some examples, the playback path circuitry 135 includes additional circuitry. For example, the playback path circuitry 135 includes amplifier circuitry to increase the drive strength of the differential pair of analog output signals.

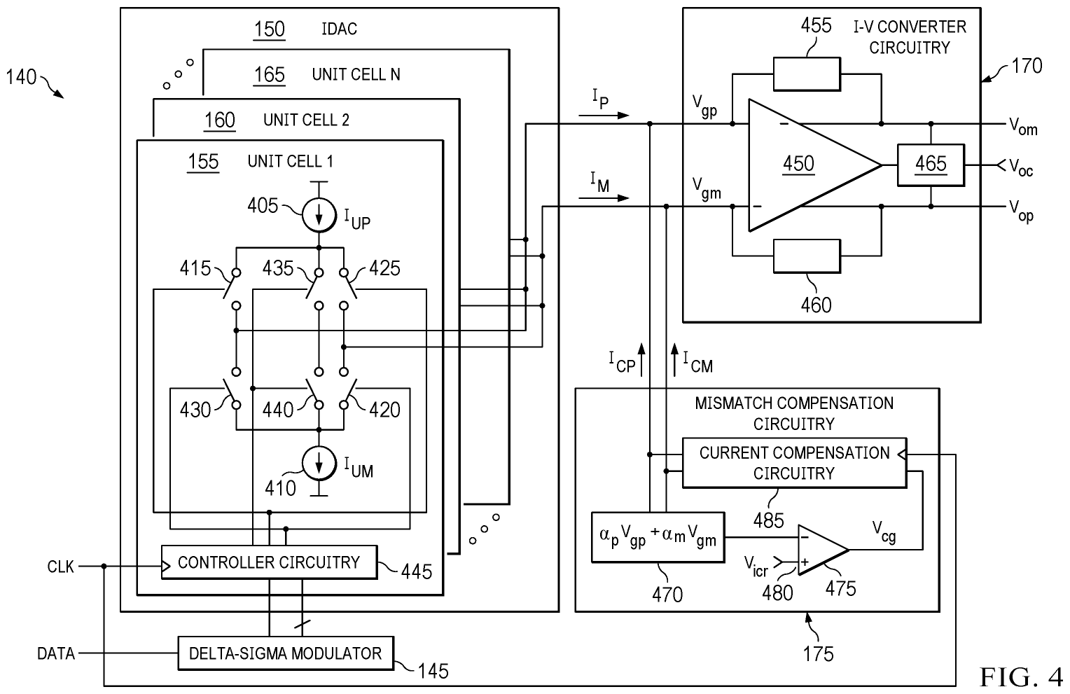

The DAC 140 has first and second inputs coupled to the logic circuitry 125 and a clock input coupled to the clock circuitry 130. The DAC 140 has first and second outputs that may be coupled to the external audio circuitry. The DAC 140 receives the digital input signals from the logic circuitry 125. The DAC 140 performs a digital-to-analog conversion. The DAC 140 converts the digital input signals into the differential pair of analog output signals. In some examples, the DAC is a class B DAC, which uses tri-level unit cells, such as the unit cells 155, 160, 165. Each unit cell may be set to one of three levels, e.g., a logical one, a logical zero, a logical minus one. Such an example is illustrated in FIG. 4 and described below. The DAC 140 supplies the differential pair of analog output signals, which the coupled external audio circuitry receives.

The delta-sigma modulator circuitry 145 has first and second inputs coupled to the logic circuitry 125. The delta-sigma modulator circuitry 145 has outputs coupled to the IDAC 150 and the unit cells 155, 160, 165. The delta-sigma modulator circuitry 145 receives the digital input signals from the logic circuitry 125. The delta-sigma modulator circuitry 145 generates a plurality of bitstreams as intermediate digital output signals. The delta-sigma modulator circuitry 145 accumulates (sigma) differences (delta) between values of the digital input signals to generate the plurality of bitstreams. In some examples, the delta-sigma modulator circuitry 145 accumulates differences across a plurality of bits. The plurality of bitstreams are over sampled representations of the digital input signals that identify logic states of the unit cells 155, 160, 165. The delta-sigma modulator circuitry 145 supplies the intermediate digital output signals to the unit cells 155, 160, 165.

The IDAC 150 has inputs coupled to the clock circuitry 130 and the delta-sigma modulator circuitry 145. The IDAC 150 has first and second outputs coupled to the I-V converter (driver) circuitry 170 and the second mismatch compensation circuitry 175. The IDAC 150 receives the intermediate digital signals from the delta-sigma modulator circuitry 145 and the clock signal from the clock circuitry 130. The IDAC 150 generates plus and minus output currents responsive to the intermediate digital signals. The plus and minus output currents are a differential pair of analog currents that represent the intermediate digital output signals. The IDAC 150 updates the plus and minus output currents responsive to the clock signal. In some examples, the IDAC 150 updates the plus and minus output currents responsive to a rising edge of the clock signal. The IDAC 150 supplies the plus and minus output currents to the I-V converter circuitry 170 and the second mismatch compensation circuitry 175.

The unit cells 155 160, 165 have inputs (not shown) coupled to the clock circuitry 130 and the delta-sigma modulator circuitry 145. The unit cells 155, 160, 165 have outputs coupled to the I-V converter circuitry 170 and the second mismatch compensation circuitry 175. The first unit cell circuitry 155 receives a first one of the intermediate digital output signals from the delta-sigma modulator circuitry 145. The first unit cell circuitry 155 determines a logic state using the first one of the intermediate digital output signals responsive to the clock signal. The logic state of the first unit cell circuitry 155 determines current contributions of the first unit cell circuitry 155 to the first and second output currents of the IDAC 150. In some examples, the first unit cell circuitry 155 operates responsive to one of three possible logic levels. Such an example of the first unit cell circuitry 155 is illustrated in FIG. 4 and described below.

Similar to the first unit cell circuitry 155, the unit cells 160, 165 each receive one of the intermediate digital output signals from the delta-sigma modulator circuitry 145. The unit cells 160, 165 operate responsive to logic states similar to the first unit cell circuitry 155. A combination of current contributions from the unit cells 155, 160, 165 generate the differential pair of plus and minus output currents of the IDAC 150. The unit cells 155, 160, 165 supply the first and second output currents to the I-V converter circuitry 170 and the second mismatch compensation circuitry 175. Although in the example of FIG. 1, the IDAC 150 includes three unit cells 155, 160, 165, the IDAC 150 may include any plurality of unit cells.

The I-V converter circuitry 170 has first and second inputs coupled to the IDAC 150, the unit cells 155, 160, 165, and the second mismatch compensation circuitry 175. The I-V converter circuitry 170 has first and second outputs that may be coupled to the external audio source, which receives the differential pair of analog output signals. The I-V converter circuitry 170 receives the plus and minus output currents from the unit cells 155, 160, 165. The I-V converter circuitry 170 receives plus and minus compensation currents from the second mismatch compensation circuitry 175. Similar to the plus and minus compensation currents of the first mismatch compensation circuitry 120, the plus and minus compensation currents from the second mismatch compensation circuitry 175 adjust a common mode voltage of the differential pair of output currents. The compensation currents are further described in FIGS. 2-6 and described further below.

The I-V converter circuitry 170 combines currents of the plus output current with the plus compensation current and the minus output current with the minus compensation current. The I-V converter circuitry 170 combines currents to modify the common mode voltage of the differential signals at the first and second inputs of the I-V converter circuitry 170. The I-V converter circuitry 170 generates the differential pair of analog output signals by converting the difference between the combined currents to voltages. Advantageously, the I-V converter circuitry 170 converts the difference between currents at the first and second inputs of the I-V converter circuitry 170 to voltages. Advantageously, magnitudes of the compensation currents may be used to modify the common mode voltage at the first and second inputs of the I-V converter circuitry 170 and reduce asymmetries.

The second mismatch compensation circuitry 175 has first and second terminals coupled to the IDAC 150, the unit cells 155, 160, 165, and the I-V converter circuitry 170. In some examples, the second mismatch compensation circuitry 175 has a clock terminal coupled to the clock circuitry 130. The second mismatch compensation circuitry 175 receives the differential pair of output currents from the unit cells 155, 160, 165. The second mismatch compensation circuitry 175 determines a common mode voltage responsive to the differential pair of output currents. The second mismatch compensation circuitry 175 determines a difference between the common mode voltage and a reference common mode voltage. The second mismatch compensation circuitry 175 generates the compensation currents responsive to differences between the common mode voltage and the reference common mode voltage. The second mismatch compensation circuitry 175 supplies the plus compensation current to the first input of the I-V converter circuitry 170 and the minus compensation current to the second input of the I-V converter circuitry 170. The second mismatch compensation circuitry 175 is similar to the first mismatch compensation circuitry 120. Examples of the mismatch compensation circuitry 120, 175 are illustrated in FIGS. 2-6 and described further below.

FIG. 2 is a schematic diagram of an example of the ADC 110 of FIG. 1 including an example of the loop filter circuitry 115 of FIG. 1 and an example of the mismatch compensation circuitry 120, 175 of FIG. 1. In the example of FIG. 2, the loop filter circuitry 115 includes a first example resistor 205, a first example amplifier 210, a first example capacitor 215, a second example resistor 220, a first example DAC 225, a third example resistor 230, a second example capacitor 235, a fourth example resistor 240, and a second example DAC 245. In the example of FIG. 2, the mismatch compensation circuitry 120 includes example common mode determination circuitry 250, a second example amplifier 255, and example current compensation circuitry 265.

In the example of FIG. 2, the illustrated and described portions of the loop filter circuitry 115 form an example first order loop filter. However, in some examples, the loop filter circuitry 115 may include one or more additional amplifiers and capacitors to implement a multiple order loop filter. For example, second order loop filter circuitry has the first amplifier 210 and another amplifier, which is coupled in series with the first amplifier 210. In such examples, the second order loop filter circuitry also has additional capacitors coupled between the inputs and output of the another amplifier to form integrator circuitry, similar to the capacitors 215, 235. Examples that include multi order loop filter circuitry further include summation circuitry to combine outputs of the amplifiers to generate a filtered output. Outputs of the summation circuitry are supplied to the DACs 225, 245 to further filter the input signals.

The first resistor 205 has a first terminal that may be coupled to external circuitry, which supplies analog input signals. The first resistor 205 has a second terminal coupled to the first amplifier 210, the first capacitor 215, the second resistor 220, the first DAC 225, the common mode determination circuitry 250, and the current compensation circuitry 265. The first resistor 205 receives a first one of the differential pair of analog input signals (VINP) from the external circuitry at the first terminal. The first resistor 205 receives a plus compensation current (I_{CP}) from the current compensation circuitry 265 at the second terminal. The first resistor 205 allows the first one of the differential pair of analog input signals and the plus compensation current to be combined at the first amplifier 210. In some examples, the first resistor 205 is referred to as a summing resistor.

The first amplifier 210 has a first input coupled to the resistors 205, 220, the first capacitor 215, the first DAC 225, the common mode determination circuitry 250, and the current compensation circuitry 265. In some examples, the first input of the first amplifier 210 is referred to as a non-inverting input and/or illustrated using a plus symbol. The first amplifier 210 has a second input coupled to the resistors 230, 240, the second capacitor 235, the second DAC 245, the common mode determination circuitry 250, and the current compensation circuitry 265. In some examples, the second input of the first amplifier 210 is referred to as an inverting input and/or illustrated using a minus symbol. The first amplifier 210 has a first output coupled to the first capacitor 215 and may be coupled to additional components of the loop filter circuitry 115. In some examples, the first output of the first amplifier 210 is referred to as an inverting output and/or illustrated using a minus symbol. The first amplifier 210 has a second output coupled to the second capacitor 235 and may be coupled to additional components of the loop filter circuitry 115. In some examples, the second output of the first amplifier 210 is referred to as a non-inverting output and/or illustrated using a plus symbol.

The first capacitor 215 has a first terminal coupled to the resistors 205, 220, the first amplifier 210, the first DAC 225, the common mode determination circuitry 250, and the current compensation circuitry 265. The first capacitor 215 has a second terminal coupled to the first amplifier 210 and may be coupled to additional components of the loop filter circuitry 115. The first capacitor 215 couples the first output and the second input of the first amplifier 210. In some examples, the first capacitor 215 is referred to as a feedback capacitor and/or more generally as an impedance circuit.

The second resistor 220 has a first terminal coupled to the first resistor 205, the first amplifier 210, the first capacitor 215, the first DAC 225, the common mode determination circuitry 250, and the current compensation circuitry 265. The second resistor 220 has a second terminal that may be coupled to additional components of the loop filter circuitry 115. The second resistor 220 couples one or more of the additional components of the loop filter circuitry 115 to the first input of the first amplifier 210. The second resistor 220 allows for one or more stages of the loop filter circuitry 115 to receive and/or supply currents at the first input of the first amplifier 210. In some examples, the second resistor 220 is referred to as a feedback resistor and/or more generally as an impedance circuit.

The first DAC 225 has inputs that may be coupled to additional components of the loop filter circuitry 115. The first DAC 225 has an output coupled to the resistors 205, 220, the first amplifier 210, the first capacitor 215, the common mode determination circuitry 250, and the current compensation circuitry 265. The first DAC 225 couples one or more of the additional components of the loop filter circuitry 115 to the first input of the first amplifier 210. The first DAC 225 receives digital input signals from the additional components of the loop filter circuitry 115. The first DAC 225 converts the digital input signals to an analog output signal. In some examples, the first DAC 225 is referred to as feedback circuitry. The first DAC 225 allows determined digital outputs of the ADC 110 to modify the first input of the first amplifier 210. In some examples, the first DAC 225 allows the loop filter circuitry 115 to determine bits of the differential pair of analog input signals a single bit at a time.

The third resistor 230 has a first terminal that may be coupled to external circuitry, which supplies analog input signals. The third resistor 230 has a second terminal coupled to the first amplifier 210, the second capacitor 235, the fourth resistor 240, the second DAC 245, the common mode determination circuitry 250, and the current compensation circuitry 265. The third resistor 230 receives a second one of the analog input signals (V_{INM}) from the external circuitry at the first terminal. The third resistor 230 receives a second compensation current (I_{CM}) from the current compensation circuitry 265 at the second terminal. The third resistor 230 allows the second one of the analog input signals and the second compensation current to be combined at the first amplifier 210. In some examples, the third resistor 230 is referred to as a summing resistor.

The second capacitor 235 has a first terminal coupled to the first amplifier 210, the resistors 230, 240, the second DAC 245, the common mode determination circuitry 250, and the current compensation circuitry 265. The second capacitor 235 has a second terminal coupled to the first amplifier 210 and may be coupled to additional components of the loop filter circuitry 115. The second capacitor 235 couples the second output and the second input of the first amplifier 210. In some examples, the second capacitor 235 is referred to as a feedback capacitor and/or more generally as an impedance circuit. However, mismatches between the capacitors 215, 235 result in asymmetries at the inputs of the first amplifier 210, which increase harmonic distortions.

The fourth resistor 240 has a first terminal coupled to the first amplifier 210, the third resistor 230, the second capacitor 235, the second DAC 245, the common mode determination circuitry 250, and the current compensation circuitry 265. The fourth resistor 240 has a second terminal that may be coupled to additional components of the loop filter circuitry 115. The fourth resistor 240 couples one or more of the additional components of the loop filter circuitry 115 to the second input of the first amplifier 210. The fourth resistor 240 allows for one or more stages of the loop filter circuitry 115 to receive and/or supply currents at the second input of the first amplifier 210. In some examples, the fourth resistor 240 is referred to as a feedback resistor and/or more generally as an impedance circuit. However, mismatches between the resistors 220, 240 result in asymmetries at the inputs of the first amplifier 210, which increase harmonic distortions.

The second DAC 245 has inputs that may be coupled to additional components of the loop filter circuitry 115. The second DAC 245 has an output coupled to the first amplifier 210, the resistors 230, 240, the second capacitor 235, the common mode determination circuitry 250, and the current compensation circuitry 265. The second DAC 245 couples one or more of the additional components of the loop filter circuitry 115 to the second input of the first amplifier 210. The second DAC 245 receives digital input signals from the additional components of the loop filter circuitry 115. The second DAC 245 converts the digital input signals to an analog output signal. In some examples, the second DAC 245 is referred to as feedback circuitry. The second DAC 245 allows determined digital outputs of the ADC 110 to modify the second input of the first amplifier 210. In some examples, the second DAC 245 allows the loop filter circuitry 115 to determine bits of the differential pair of analog input signals a single bit at a time. However, mismatches between components of the DACs 225, 245 result in asymmetries at the inputs of the first amplifier 210, which increase harmonic distortions.

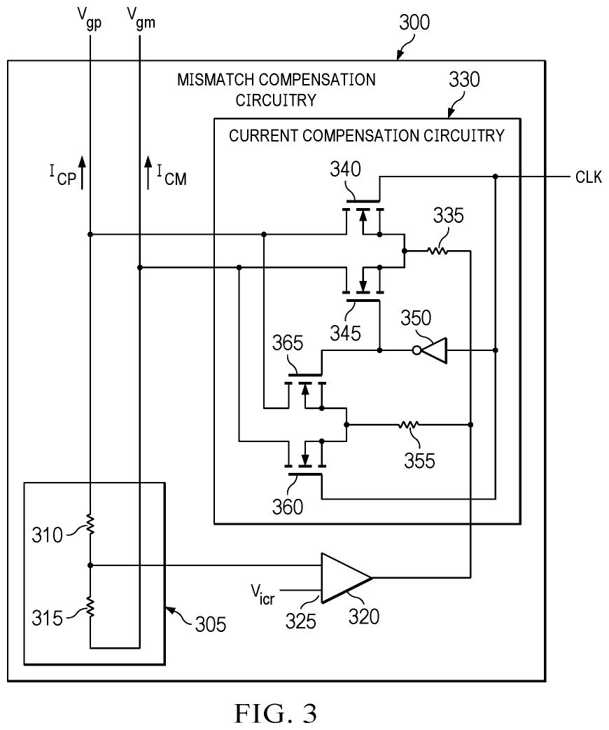

The common mode determination circuitry 250 has a first input coupled to the resistors 205, 220, the first amplifier 210, the first capacitor 215, the first DAC 225, and the current compensation circuitry 265. The common mode determination circuitry 250 has a second input coupled to the first amplifier 210, the resistors 230, 240, the second capacitor 235, the second DAC 245, and the current compensation circuitry 265. The common mode determination circuitry 250 has an output coupled to the second amplifier 255. The common mode determination circuitry 250 receives the plus side voltage and the minus side voltage of the inputs of the first amplifier 210. The common mode determination circuitry 250 determines a common mode voltage of the plus side voltage and the minus side voltage. In some examples, the common mode determination circuitry 250 determines the common mode voltage to be a mid-point between the plus and minus side voltages. Such an example is illustrated in FIG. 3 and described below. The common mode determination circuitry 250 supplies the common mode voltage to the second amplifier 255.

The second amplifier 255 has a first input coupled to the common mode determination circuitry 250 and a second input coupled to an example reference common mode voltage (V_{icr}) 260. The second amplifier 255 receives the common mode voltage and the reference common mode voltage 260. The second amplifier 255 compares the common mode voltage to the reference common mode voltage 260. The reference common mode voltage 260 is a voltage representing a target common mode voltage of the analog input signals. In some examples, the reference common mode voltage 260 is a common potential (e.g., ground). The second amplifier 255 determines a common mode error proportional to a result of the comparison. Asymmetries of the differential pair of analog input signals or of currents from mismatching feedback components, such as the capacitors 215, 235, the resistors 220, 240, and/or the DACs 225, 245, shift the common mode voltage and increase the common mode error. The second amplifier 255 supplies the common mode error to current compensation circuitry 265.

The current compensation circuitry 265 has a first input coupled to the second amplifier 255. In some examples, the current compensation circuitry 265 has a clock input coupled to the clock circuitry 130 of FIG. 1, which supplies the clock signal. The current compensation circuitry 265 has a first output coupled to the resistors 205, 220, the first amplifier 210, the first capacitor 215, the first DAC 225, and the common mode determination circuitry 250. The current compensation circuitry 265 has a second output coupled to the first amplifier 210, the resistors 230, 240, the second capacitor 235, the second DAC 245, and the common mode determination circuitry 250. The current compensation circuitry 265 receives the common mode error from the second amplifier 255. The current compensation circuitry 265 generates the plus and minus compensation currents responsive to the common mode error. In some examples, the current compensation circuitry 265 generates the plus and minus compensation currents by converting voltages of the common mode error to currents. Such an example is illustrated in FIG. 3 and described further below.

In some examples, such as the example of FIG. 3, the current compensation circuitry 265 includes switching circuitry. In such examples, the switching circuitry alternates the supply of first and second compensation currents between the outputs of the current compensation circuitry 265 to generate the plus and minus compensation currents. For example, during a first duration of a cycle of the clock signal, the current compensation circuitry 265 supplies the first compensation current as the plus compensation current and the second compensation current as the minus compensation current. In such examples, during a second duration of the cycle of the clock signal, the current compensation circuitry 265 supplies the second compensation current as the plus compensation current and the first compensation current as the minus compensation current. Advantageously, switching the supply of compensation currents between outputs of the current compensation circuitry 265 reduces errors resulting from mismatch between the compensation currents.

The current compensation circuitry 265 supplies the plus and minus compensation currents to the inputs of the first amplifier 210. Advantageously, the plus and minus compensation currents adjust the common mode voltage of the first and second inputs of the first amplifier 210 to be approximately equal to the reference common mode voltage 260. Advantageously, the plus and minus compensation currents correct the common mode voltage of the inputs of the first amplifier 210 for asymmetries responsive to mismatch between current contributions by the resistors 205, 220, 230, 240, the capacitors 215, 235, and/or the DACs 225, 245.

FIG. 3 is a schematic diagram of example mismatch compensation circuitry 300. The mismatch compensation circuitry 300 of FIG. 3 is an example of the mismatch compensation circuitry 120, 175 of FIGS. 1 and 2. In the example of FIG. 3, the mismatch compensation circuitry 300 includes example common mode determination circuitry 305, an example amplifier 320, and example current compensation circuitry 330. The common mode determination circuitry 305 includes a first example resistor 310 and a second example resistor 315. The example current compensation circuitry 330 includes a third example resistor 335, a first example transistor 340, a second example transistor 345, an example inverter 350, a fourth example resistor 355, a third example transistor 360, and a fourth example transistor 365.

In some examples, the mismatch compensation circuitry 300 is coupled to the loop filter circuitry 115 of FIGS. 1 and 2. In such examples, the mismatch compensation circuitry 300 receives a plus side voltage (V_{GP}) and a minus side voltage (V_{GM}) from the loop filter circuitry 115. In other examples, the mismatch compensation circuitry 300 is coupled to the IDAC 150 of FIG. 1 and the I-V converter circuitry 170 of FIG. 1. In such examples, the mismatch compensation circuitry 300 receives the plus and minus side voltages from the I-V converter circuitry 170. In both examples, the mismatch compensation circuitry 300 supplies a first compensation current (I_{CP}) and a second compensation current (I_{CM}) to compensate the plus and minus side voltages for mismatch.

In example operations, mismatches between the plus and minus side voltages are responsive to non-ideal current contributions from components. Ideally, currents and voltages of signals of a differential pair of signals should have approximately the same magnitude. However, magnitudes of currents and voltages of a differential pair of signals may drift responsive to non-ideal characteristics of components, such as manufacturing tolerances, parasitic elements, temperature variations, etc. The first and second compensation currents of the mismatch compensation circuitry 300 adjust the common mode voltage of the differential pair of signals by approximately the same value. The mismatch compensation circuitry 300 compensates the plus and minus side voltages of a differential pair of signals at inputs of the first amplifier 210 of FIG. 2. Advantageously, the first amplifier 210 uses the differential of the compensated plus and minus voltages to determine the value of the differential pair of signals.

The common mode determination circuitry 305 has first and second terminals coupled to the transistors 340, 345, 360, 365 and that may be coupled to inputs of an amplifier (e.g., the first amplifier 210). The common mode determination circuitry 305 has a third terminal coupled to the amplifier 320. The common mode determination circuitry 305 receives a differential pair of voltages from inputs of the first amplifier 210. The differential pair of voltages includes a plus side voltage, which represents a first input of the amplifier, and a minus side voltage, which represents a second input of the first amplifier 210. The common mode determination circuitry 305 determines the common mode voltage of the plus and minus side voltages. Asymmetries between magnitudes of the plus and minus voltages shift the common mode voltage of the differential pair of voltages. The common mode determination circuitry 305 supplies the common mode voltage to the amplifier 320. The common mode determination circuitry 305 is an example implementation of the common mode determination circuitry 250 of FIG. 2.

The first resistor 310 has a first terminal coupled to the transistors 340, 365 and may be coupled to the first amplifier 210. The first resistor 310 has a second terminal coupled to the second resistor 315 and the amplifier 320. The second resistor 315 has a first terminal coupled to the transistors 345, 360 and may be coupled to the first amplifier 210. The second resistor 315 has a second terminal coupled to the first resistor 310 and the amplifier 320.

The resistors 310, 315 each have approximately the same resistance. The first resistor 310 receives the plus side voltage, and the second resistor 315 receives the minus side voltage. The difference between the plus and minus side voltages is applied across the resistors 310, 315. The resistors 310, 315 divide the difference between the plus and minus side voltages evenly between each of the resistors 310, 315. The resistors 310, 315 generate an approximate of the common mode voltage of the plus and minus voltages responsive to the voltage drops across each of the resistors 310, 315. The resistors 310, 315 approximate the common mode voltage between the plus and minus voltage to be a voltage approximately halfway between the plus and minus side voltages. The resistors 310, 315 provide the approximated common mode voltage to the amplifier 320.

The amplifier 320 has a first input coupled to the resistors 310, 315 and a second input that receives a reference common mode voltage 325. The amplifier 320 has an output coupled to the resistors 335, 355. The amplifier 320 receives the common mode voltage at the second terminals of the resistors 310, 315. The amplifier 320 compares the common mode voltage to the reference common mode voltage 325. The reference common mode voltage 325 is an example of the reference common mode voltage 260 of FIG. 2. The reference common mode voltage 325 is a target common mode voltage of the plus and minus side voltages. The amplifier 320 determines a difference between the common mode voltage and the reference common mode voltage 325. The amplifier 320 generates a common mode error voltage responsive to the differences between the voltages at the first and second input. The amplifier 320 provides the common mode error voltage at terminals of the resistors 335, 355.

The current compensation circuitry 330 has a first input coupled to the amplifier 320. In some examples, such as in FIG. 3, the current compensation circuitry 330 has a clock input that may be coupled to the clock circuitry 130, which provides the clock signal. The current compensation circuitry 330 has a first output coupled to the first resistor 310 and may be coupled to the first amplifier 210. The current compensation circuitry 230 has a second output coupled to the second resistor 315 and may be coupled to the first amplifier 210. The current compensation circuitry 330 is an example of the current compensation circuitry 265 of FIG. 2.

The third resistor 335 has a first terminal coupled to the amplifier 320 and the fourth resistor 355. The third resistor 335 has a second terminal coupled to the transistors 340, 345. The third resistor 335 receives the common mode error voltage from the amplifier 320. The third resistor 335 converts the common mode error voltage into a first compensation current responsive to a resistance of the third resistor 335. The transistors 340, 345 receive the first compensation current.

The first transistor 340 has a first terminal coupled to the third resistor 335 and the second transistor 345. The first transistor 340 has a second terminal coupled to the first resistor 310, the fourth transistor 365, and may be coupled to the first amplifier 210. The first transistor 340 has a control terminal that may be coupled to the clock circuitry 130, which supplies the clock signal. When enabled (e.g., conducting), the first transistor 340 passes a current responsive to the current from the third resistor 335. When disabled (e.g., non-conducting), the first transistor 340 prevents or blocks the current from the third resistor 335. In example operation, during a first half of a cycle of the clock signal, the first transistor 340 compensates the plus side voltage using the first compensation current from the third resistor 335. In such examples, during a second half of a cycle of the clock signal, the first transistor 340 prevents the third resistor 335 from compensating the plus side voltage with the first compensation current.

The second transistor 345 has a first terminal coupled to the third resistor 335 and the first transistor 340. The second transistor 345 has a second terminal coupled to the second resistor 315, the third transistor 360, and may be coupled to the first amplifier 210. The second transistor 345 has a control terminal coupled to the inverter 350. When enabled, the second transistor 345 allows the third resistor 335 to supply current to the minus side voltage. When disabled, the second transistor 345 prevents the third resistor 335 from supplying current to the minus side voltage.

The inverter 350 has an input that may be coupled to the clock circuitry 130, which supplies the clock signal. The inverter 350 has an output coupled to the transistors 345, 365. The inverter 350 receives the clock signal from the clock circuitry 130. The inverter 350 inverts the clock signal using a logic NOT operation, which generates an inverted clock signal. The inverter 350 controls the transistors 345, 365 using the inverted clock signal. In example operations, during the first half of a cycle of the clock signal, the second transistor 345 prevents the third resistor 335 from compensating the minus side voltage with the first compensation current. In such examples, during the second half of a cycle of the clock signal, the second transistor 345 compensates the minus side voltage using the first compensation current from the third resistor 335. Advantageously, the inverter 350 switches, e.g., enables and disables, the transistors 345, 365 opposite of the transistors 340, 360.

The fourth resistor 355 has a first terminal coupled to the amplifier 320 and the third resistor 335. The fourth resistor 355 has a second terminal coupled to the transistors 360, 365. The fourth resistor 355 receives the common mode error voltage from the amplifier 320. The fourth resistor 355 converts the common mode error voltage into a second compensation current responsive to a resistance of the fourth resistor 355. The fourth resistor 355 supplies the second compensation current to the transistors 360, 365.

The third transistor 360 has a first terminal coupled to the fourth resistor 355 and the fourth transistor 365. The third transistor 360 has a second terminal coupled to the second resistor 315, the second transistor 345, and may be coupled to the first amplifier 210. The third transistor 360 has a control terminal that may be coupled to the clock circuitry 130, which supplies the clock signal. When enabled, the third transistor 360 passes a current responsive to the current from the fourth resistor 355. When disabled, the third transistor 360 prevents or blocks the current from the fourth resistor 355. In example operation, during a first half cycle of a cycle of the clock signal, the third transistor 360 compensates the minus side voltage using the second compensation current from the fourth resistor 355. In such examples, during a second half cycle of the cycle of the clock signal, the third transistor 360 prevents the fourth resistor 355 from compensating the minus side voltage with the second compensation current.

The fourth transistor 365 has a first terminal coupled to the fourth resistor 355 and the third transistor 360. The fourth transistor 365 has a second terminal coupled to the first resistor 310, the first transistor 340, and may be coupled to the first amplifier 210. The fourth transistor 365 has a control terminal coupled to the inverter 350. When enabled, the fourth transistor 365 passes a current responsive to the current from the fourth resistor 355. When disabled, the second transistor 345 prevents or blocks the current from the fourth resistor 355. In the example of FIG. 3, the current compensation circuitry 330 includes the transistors 340, 345, 360, 365. However, the current compensation circuitry 330 may include alternative circuitry and/or illustrate and describe operations of the transistors 340, 345, 360, 365 using switches or alternative components.

FIG. 4 is a schematic diagram of an example of the DAC 140 of FIG. 1. In the example of FIG. 4, the DAC 140 includes the delta-sigma modulator circuitry 145 of FIG. 1, the IDAC 150 with the unit cells 155, 160, 165 of FIG. 1, the I-V converter circuitry 170 of FIG. 1, and the second mismatch compensation circuitry 175 of FIG. 1.

In the example of FIG. 4, the first unit cell circuitry 155 includes first example current source circuitry 405, second example current source circuitry 410, a first example switch 415, a second example switch 420, a third example switch 425, a fourth example switch 430, a fifth example switch 435, a sixth example switch 440, and example controller circuitry 445. In the example of FIG. 4, the I-V converter circuitry 170 includes a first example amplifier 450, a first example impedance circuit 455, a second example impedance circuit 460, and example common mode feedback circuitry 465. In the example of FIG. 4, the second mismatch compensation circuitry 175 includes example common mode determination circuitry 470, a second example amplifier 475, an example reference common mode voltage 480, and example current compensation circuitry 485.

In the example of FIG. 4, the unit cells 155, 160, 165 generate a differential pair of currents responsive to the intermediate digital output signals from the delta-sigma modulator circuitry 145. The differential pair of currents include plus and minus output currents. The unit cells 155, 160, 165 may contribute currents to one or both of the plus and minus output currents. In some examples, the first unit cell 155 contributes to the plus and minus output currents, and the second unit cell 160 fails to contribute to the plus and minus output currents. In the example of FIG. 4, only circuitry of the first unit cell 155 is illustrated. However, the circuitry of the first unit cell 155 may be replicated for each of the unit cells 160, 165. Alternatively, the IDAC 150 of FIGS. 1 and 4 may include any number of instances of one or more of the unit cells 155, 160, 165. In some examples, the number of unit cells corresponds to a number of bits used to represent an analog value.

The first current source circuitry 405 has a first terminal coupled to a supply terminal, which supplies a supply voltage. The first current source circuitry 405 has a second terminal coupled to the switches 415, 425, 435. The first current source circuitry 405 supplies a first reference current (I_{UP}) to the switches 415, 425, 435. In some examples, the first current source circuitry 405 contributes the first reference current to one of the plus or minus side output currents by the switches 415, 425. In such examples, the first current source circuitry 405 fails to contribute the first reference current to either of the plus or minus side output currents by the fifth switch 435.

The second current source circuitry 410 has a first terminal coupled to the switches 420, 430, 440. The second current source circuitry 410 has a second terminal coupled to a common terminal, which supplies a common potential (e.g., ground, V_{SS}, etc.). The second current source circuitry 410 sinks a second reference current (I_{UM}) from the switches 420, 430, 440. In some examples, the second current source circuitry 410 contributes the second reference current to one of the plus or minus side output currents by the switches 415, 425. In such examples, the second current source circuitry 410 fails to contribute the second reference current to either of the plus or minus side output currents by the sixth switch 440.

The first switch 415 has a first terminal coupled to the first current source circuitry 405 and the switches 425, 435. The first switch 415 has a second terminal coupled to the fourth switch 430, the first amplifier 450, the first impedance circuit 455, the common mode determination circuitry 470, and the current compensation circuitry 485. The first switch 415 has a control terminal coupled to the controller circuitry 445. The controller circuitry 445 controls the first switch 415. When closed, the first switch 415 receives the first reference current from the first current source circuitry 405. In such examples, the first switch 415 supplies the first reference current to the first amplifier 450 and/or the first impedance circuit 455. When open, the first switch 415 prevents the first reference current from being supplied to the first amplifier 450 and/or the first impedance circuit 455.

The second switch 420 has a first terminal coupled to the third switch 425, the first amplifier 450, the second impedance circuit 460, the common mode determination circuitry 470, and the current compensation circuitry 485. The second switch 420 has a second terminal coupled to the second current source circuitry 410 and the switches 430, 440. The second switch 420 has a control terminal coupled to the controller circuitry 445. The controller circuitry 445 controls the second switch 420. When closed, the second switch 420 allows the second current source circuitry 410 to sink the second reference current from the first amplifier 450 and/or the second impedance circuit 460. When open, the second switch 420 prevents the second current source circuitry 410 from sinking the second reference current from the first amplifier 450 and/or the second impedance circuit 460.

The third switch 425 has a first terminal coupled to the first current source circuitry 405 and the switches 415, 435. The third switch 425 has a second terminal coupled to the second switch 420, the first amplifier 450, the second impedance circuit 460, the common mode determination circuitry 470, and the current compensation circuitry 485. The third switch 425 has a control terminal coupled to the controller circuitry 445. The controller circuitry 445 controls the third switch 425. When closed, the third switch 425 receives the first reference current from the first current source circuitry 405. In such examples, the third switch 425 supplies the first reference current to the first amplifier 450 and/or the second impedance circuit 460. When open, the third switch 425 prevents the first reference current from being supplied to the first amplifier 450 and/or the second impedance circuit 460.

The fourth switch 430 has a first terminal coupled to the first switch 415, the first amplifier 450, the first impedance circuit 455, the common mode determination circuitry 470, and the current compensation circuitry 485. The fourth switch 430 has a second terminal coupled to the second current source circuitry 410 and the switches 420, 440. The fourth switch 430 has a control terminal coupled to the controller circuitry 445. The controller circuitry 445 controls the fourth switch 430. When closed, the fourth switch 430 allows the second current source circuitry 410 to sink the second reference current from the first amplifier 450 and/or the first impedance circuit 455. When open, the fourth switch 430 prevents the second current source circuitry 410 from sinking the second reference current from the first amplifier 450 and/or the first impedance circuit 455.

The fifth switch 435 has a first terminal coupled to the first current source circuitry 405 and the switches 415, 425. The fifth switch 435 has a second terminal coupled to the sixth switch 440. The fifth switch 435 has a control terminal coupled to the controller circuitry 445. The controller circuitry 445 controls the fifth switch 435. When closed, the fifth switch 435 receives the first reference current from the first current source circuitry 405. In such examples, the fifth switch 435 supplies the first reference current to the sixth switch 440. When open, the fifth switch 435 prevents the first reference current from being supplied to the sixth switch 440.

The sixth switch 440 has a first terminal coupled to the fifth switch 435. The sixth switch 440 has a second terminal coupled to the second current source circuitry 410 and the switches 420, 430. The sixth switch 440 has a control terminal coupled to the controller circuitry 445. The controller circuitry 445 controls the sixth switch 440. When closed, the sixth switch 440 allows the second current source circuitry 410 to sink the second reference current from the fifth switch 435. When open, the sixth switch 440 prevents the second current source circuitry 410 from sinking the second reference current from the fifth switch 435.

The controller circuitry 445 has inputs coupled to the delta-sigma modulator circuitry 145 and that may be coupled to the clock circuitry 130 of FIG. 1. The controller circuitry 445 has outputs coupled to the switches 415, 420, 425, 430, 435, 440. The controller circuitry 445 receives the clock signal from the clock circuitry 130. The controller circuitry 445 receives the intermediate digital output signals from the delta-sigma modulator circuitry 145. The controller circuitry 445 controls the switches 415, 420, 425, 430, 435, 440 responsive to the intermediate digital output signals and the clock signal. The controller circuitry 445 uses one of the intermediate digital output signals to determine a logic state of the first unit cell circuitry 155. In the example of FIG. 4, the first unit cell circuitry 155 may be in one of a logical one state, a logical minus one state, or a logical zero state.

In the logical one state, the controller circuitry 445 closes the switches 415, 420 and opens the switches 425, 430, 435, 440. In such a state, the first unit cell circuitry 155 supplies the first reference current to the first amplifier 450 and the first impedance circuit 455 and sinks the second reference current from the first amplifier and the second impedance circuit 460. In some examples, the first and second reference currents of the current source circuitry 405, 410 have approximately the same magnitude. In such examples, the first and second reference currents form a differential pair of signals. Ideally, in the logical one state, the first and second reference currents have approximately the same magnitude in opposite directions.

However, asymmetries at the inputs of the first amplifier 450 are responsive to mismatches between the magnitudes of the first and second reference currents from the switches 415, 420.

In the logical minus one state, the controller circuitry 445 closes the switches 425, 430 and opens the switches 415, 420, 435, 440. In such a state, the first unit cell circuitry 155 supplies the first reference current to the first amplifier 450 and the second impedance circuit 460 and sinks the second reference current from the first amplifier and the first impedance circuit 455. The first unit cell circuitry 155 contributes inverse currents in the logical minus one state compared to the logical one state.

In the logical zero state, the controller circuitry 445 closes the switches 435, 440 and opens the switches 415, 420, 425, 430. In such a state, the first unit cell circuitry 155 couples the current source circuitry 405, 410. When coupled, the second current source circuitry 410 sinks the first reference current from the first current source circuitry 405. Advantageously, when in the logical zero state, the first unit cell circuitry 155 does not contribute to the currents supplied to the first amplifier and the impedance circuitry 455, 460.

The first amplifier 450 has a first input coupled to the unit cells 155, 160, 165, the switches 415, 430, the first impedance circuit 455, the common mode determination circuitry 470, and the current compensation circuitry 485. The first amplifier 450 has a second input coupled to the unit cells 155, 160, 165, the switches 420, 425, the second impedance circuit 460, the common mode determination circuitry 470, and the current compensation circuitry 485. The first amplifier 450 has a first output coupled to the first impedance circuit 455, the common mode feedback circuitry 465, and may be coupled to external circuitry, such as a speaker, amplifier, etc. The first amplifier 450 has a second output coupled to the second impedance circuit 460, the common mode feedback circuitry 465, and may be coupled to the external circuitry. In some examples, the first amplifier 450 has a third output coupled to the common mode feedback circuitry 465.

A voltage of the first input of the first amplifier 450 may be referred to as a plus side voltage (V_{GP}). The plus side voltage of the first amplifier 450 is responsive to current contributions of the unit cells 155, 160, 165. For example, the plus side voltage is a first value when the unit cells 155, 160 are in a logical one state, when the third unit cell circuitry 165 is in a logical zero state. In such examples, the plus side voltage is a second value when the first unit cell circuitry 155 is in a logical one state when the unit cells 160, 165 are in a logical zero state. Also, a plus side compensation current (I_{CP}) from the current compensation circuitry 485 may further modify the plus side voltage of the first amplifier 450 responsive to modifying current flowing through the first impedance circuit 455. Advantageously, currents from the current compensation circuitry 485 may modify the plus side voltage of the first amplifier 450.

A voltage of the second input of the first amplifier 450 may be referred to as a minus side voltage (V_{GM}). The minus side voltage of the first amplifier 450 is responsive to current contributions of the unit cells 155, 160, 165. For example, the minus side voltage is a first value when the unit cells 155, 160 are in a logical one state when the third unit cell circuitry 165 is in a logical zero state. In such examples, the minus side voltage is a second value when the first unit cell circuitry 155 is in a logical one state when the unit cells 160, 165 are in a logical zero state. Also, a minus side compensation current (I_{CM}) from the current compensation circuitry 485 may further modify the minus side voltage of the first amplifier 450 responsive to modifying current flowing through the second impedance circuit 460. Advantageously, currents from the current compensation circuitry 485 may modify the minus side voltage of the first amplifier 450.

The first amplifier 450 receives currents from the unit cells 155, 160, 165, the impedance circuits 455, 460, and the current compensation circuitry 485. The first amplifier 450 supplies the plus and minus voltages to the common mode determination circuitry 470. During example operations, currents from the current compensation circuitry 485 modifies the plus and minus voltages. In such example operations, the currents from the current compensation circuitry 485 compensate the plus and minus voltages for mismatch. The first amplifier 450 generates plus and minus output voltages at the first and second outputs. The plus and minus output voltages are voltages representing the analog output signals of the DAC 140.

The first impedance circuit 455 has a first terminal coupled to the unit cells 155, 160, 165, the switches 415, 430, the first amplifier 450, the common mode determination circuitry 470, and the current compensation circuitry 485. The first impedance circuit 455 has a second terminal coupled to the first amplifier 450, the common mode feedback circuitry 465, and may be coupled to the external circuitry. The first impedance circuit 455 couples the first input of the first amplifier 450 to the first output of the first amplifier 450. The first impedance circuit 455 may be referred to as feedback circuitry. In some examples, the first impedance circuit 455 includes a resistive component to set a gain, capacitances to integrate an input, etc. In the example of FIG. 4, the plus side compensation current from the current compensation circuitry 485 modifies the current flowing through the first impedance circuit 455. Such a modification accounts for mismatches and reduces THD. Advantageously the plus side compensation current contributes to current of the first impedance circuit 455 to compensate for mismatch and reduce THD.

The second impedance circuit 460 has a first terminal coupled to the unit cells 155, 160, 165, the switches 420, 425, the first amplifier 450, the common mode determination circuitry 470, and the current compensation circuitry 485. The second impedance circuit 460 has a second terminal coupled to the first amplifier 450, the common mode feedback circuitry 465, and may be coupled to the external circuitry. The second impedance circuit 460 couples the second input of the first amplifier 450 to the second output of the first amplifier 450. The second impedance circuit 460 may be referred to as feedback circuitry. In some examples, the second impedance circuit 460 includes a resistive component to set a gain, capacitances to integrate an input, etc. In the example of FIG. 4, the minus side compensation current from the current compensation circuitry 485 modifies the current flowing through the second impedance circuit 460. Such a modification accounts for mismatches and reduces THD. Advantageously the minus side compensation current contributes to current of the second impedance circuit 460 to compensate for mismatch and reduce THD.

In some examples, the impedance circuits 455, 460 are designed to have approximately the same impedance. In such examples, the impedance circuits 455, 460 may include components of the same value. However, variations may result in mismatches between the impedance circuits 455, 460, such as variations in tolerances, process, environmental conditions, etc. Such mismatches between the impedance circuits 455, 460 further contribute to mismatches between the plus and minus voltages of the first amplifier 450.

The common mode feedback circuitry 465 is coupled to outputs of the first amplifier 450 and the impedance circuits 455, 460. The common mode feedback circuitry 465 regulates a common mode voltage of the plus and minus output voltages of the first amplifier 450. In some examples, the common mode feedback circuitry 465 receives a reference voltage as a target output common mode voltage (V_{OC}) of the plus and minus output voltages. In such examples, the common mode feedback circuitry 465 compensates the plus and minus output voltages to set the common mode voltage of the outputs of the first amplifier 450 approximately equal to the target output common mode voltage. In example operations, the common mode feedback circuitry 465 compensates the outputs of the first amplifier 450 to have a common mode voltage approximately equal to the target output common mode voltage.

The common mode determination circuitry 470 has a first input coupled to the unit cells 155, 160, 165, the switches 415, 430, the first amplifier 450, the first impedance circuit 455, and the current compensation circuitry 485. The common mode determination circuitry 470 has a second input coupled to the unit cells 155, 160, 165, the switches 420, 425, the first amplifier 450, the second impedance circuit 460, and the current compensation circuitry 485. The common mode determination circuitry 470 receives the plus and minus input voltages of the first amplifier 450. The common mode determination circuitry 470 is another example implementation of the common mode determination circuitry 250, 305 of FIGS. 2 and 3. The common mode determination circuitry 470 determines a common mode voltage of the plus and minus input voltages. The common mode determination circuitry 470 supplies the common mode voltage to the second amplifier 475.

The second amplifier 475 has a first input coupled to the common mode determination circuitry 470 and a second input coupled to the reference common mode voltage 480. The second amplifier 475 has an output coupled to the current compensation circuitry 485. The second amplifier 475 receives the common mode voltage from the common mode determination circuitry 470. The second amplifier 475 is another example implementation of the amplifiers 255, 320 of FIGS. 2 and 3. The second amplifier 475 determines a common mode error voltage responsive to differences between the common mode voltage and the reference common mode voltage 480. The second amplifier 475 supplies the common mode error voltage to the current compensation circuitry 485.

The current compensation circuitry 485 has a first input coupled to the second amplifier 475. In some examples, the current compensation circuitry 485 has a clock input coupled to the clock circuitry 130, which supplies the clock signal. The current compensation circuitry 485 receives the common mode error voltage from the second amplifier 475. The current compensation circuitry 485 is another example implementation of the current compensation circuitry 265, 330 of FIGS. 2 and 3. The current compensation circuitry 485 generates plus and minus side compensation currents responsive to the common mode error voltage. The current compensation circuitry 485 supplies the plus side compensation current to the first input of the first amplifier 450 and the minus side compensation current to the second input of the first amplifier 450. Advantageously, the plus and minus side compensation currents compensate the plus and minus input voltages of the first amplifier 450 for mismatch.

In example operations, the I-V converter circuitry 170 converts the differential pair of currents at the inputs of the first amplifier 450 to voltages representing the differential pair of analog output signals. In some example operations, when the first unit cell 155 is set to a logical one state, the plus side output currents at a first input of the first amplifier 450 are approximately equal the first reference current (I_{UP}) plus the plus compensation current (I_{CP}). In such example operations, the minus side output currents at a second input of the first amplifier 450 are approximately equal to the second reference current (I_{UM}) plus the minus compensation current (I_{CM}). However, non-ideal asymmetries between the first and second reference currents (Δ_{U}) of the current source circuitry 405, 410, vary the first and second reference current. For example, the first reference current is approximately equal to one plus Δ_{U} and the second reference current is approximately equal to one minus Δ_{U}. Similarly, non-ideal mismatches between the impedances (r_{f}) of the impedance circuits 455, 460 vary the impedances. For example, the first impedance circuit 455 is a value approximately equal to one plus r_{f} and the second impedance circuit 460 is a value approximately equal to one minus r_{f}.

In such example operations, the mismatch compensation circuitry 175 generates the compensation currents to account for the non-ideal asymmetries between the first and second reference currents and the impedance circuits 455, 460. However, the non-ideal mismatches between the impedance circuits 455, 460 appear again during the current to voltage conversion of the I-V converter circuitry 170. In example operations, a plus side combined current is approximately equal to one minus the mismatch between the impedances and the minus side combined current is approximately equal to minus one minus the mismatch between impedances. In such examples, a first voltage at the first output of the first amplifier 450 is approximately equal to the plus side combined current (e.g., 1−r_{f}) times the value of the first impedance circuit 455 (e.g., 1+r_{f}). A second voltage at the second output of the first amplifier 450 is approximately equal to the minus side combined current (e.g., −1−r_{f}) times the value of the first impedance circuit 455 (e.g., 1−r_{f}). Accordingly, the difference between the plus and minus side output voltages is a differential voltage (e.g., 2(1−r_{f}²)) that represents the differential pair of analog output signals. Advantageously, the differential voltage of the differential pair of analog output signals has a linear value across a plurality of frequencies. Advantageously, the compensation currents from the mismatch compensation circuitry 175 reduce non-linearities of the differential pair of analog output signals across a range of frequencies.

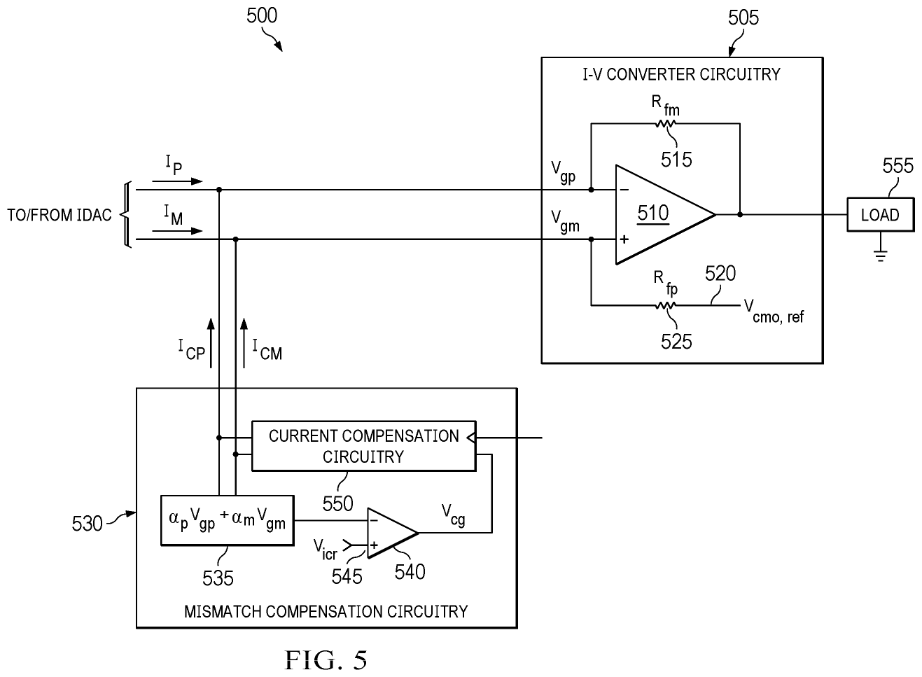

FIG. 5 is a schematic diagram of another example implementation of the mismatch compensation circuitry 120, 175, 300 of FIGS. 1, 2, 3, and 4 in an example DAC 500. In the example of FIG. 5, the DAC 500 includes example current-to-voltage (I-V) converter circuitry 505, example mismatch compensation circuitry 530, and an example load 555. In the example of FIG. 5, the I-V converter circuitry 505 includes a first example amplifier 510, a first example resistor 515, a reference output common mode voltage 520, a second example resistor 525. In the example of FIG. 5, the mismatch compensation circuitry 530 includes example common mode determination circuitry 535, a second example amplifier 540, a reference common mode voltage 545, and example current compensation circuitry 550. The DAC 500 is an example implementation of the DAC 140 of FIGS. 1 and 4 that has been modified to supply a single ended analog output signal to the load 555. Also, the DAC 500 may include one or more components of the DAC 140 that are not illustrated (for simplicity). For example, the DAC 500 includes the delta-sigma modulator circuitry 145 of FIGS. 1 and 4, the IDAC 150 of FIGS. 1 and 4, and the unit cells 155, 160, 165 of FIGS. 1 and 4.

The I-V converter circuitry 505 has first and second inputs coupled to the mismatch compensation circuitry 530 and that may be coupled to the IDAC 150. The I-V converter circuitry 505 has an output coupled to the load 555. In the example of FIG. 5, the I-V converter circuitry 505 includes the first amplifier 510, the resistors 515, 525, and the reference output common mode voltage 520. The I-V converter circuitry 505 receives the plus and minus side currents from the IDAC 150 and the plus and minus side compensation currents from the mismatch compensation circuitry 530. The I-V converter circuitry 505 is an example implementation of the I-V converter circuitry 170 of FIGS. 1 and 4. Unlike the I-V converter circuitry 170, the I-V converter circuitry 505 of FIG. 5 converts the differential pair of input currents into a single ended output. The I-V converter circuitry 505 supplies the analog output signal as the single ended output to a load.

The first amplifier 510 has a first input coupled to the first resistor 515, the mismatch compensation circuitry 530, the common mode determination circuitry 535, and the current compensation circuitry 550, and may be coupled to the IDAC 150. The first amplifier 510 has a second input coupled to the second resistor 525, the mismatch compensation circuitry 530, the common mode determination circuitry 535, and the current compensation circuitry 550 and may be coupled to the IDAC 150. The first amplifier 510 has an output coupled to the first resistor 515 and the load 555.

The first resistor 515 has a first terminal coupled to the first amplifier 510, the mismatch compensation circuitry 530, the common mode determination circuitry 535, and the current compensation circuitry 550 and may be coupled to the IDAC 150. The first resistor 515 has a second terminal coupled to the first amplifier 510 and the load 555.

The reference output common mode voltage 520 is coupled to the second resistor 525. The reference output common mode voltage 520 represents a desired common mode voltage of the single ended output of the first amplifier 510. In some examples, the reference output common mode voltage 520 is a voltage source.

The second resistor 525 has a first terminal coupled to the first amplifier 510, the mismatch compensation circuitry 530, the common mode determination circuitry 535, and the current compensation circuitry 550 and may be coupled to the IDAC 150. The second resistor 525 has a second terminal coupled to the reference output common mode voltage 520.

The mismatch compensation circuitry 530 is coupled to the I-V converter circuitry 505, the first amplifier 510, and the resistors 515, 525 and may be coupled to the IDAC 150. In the example of FIG. 5, the mismatch compensation circuitry 530 includes the common mode determination circuitry 535, the second amplifier 540, the reference common mode voltage 545, and the current compensation circuitry 550. The mismatch compensation circuitry 530 of FIG. 5 is another example implementation of the mismatch compensation circuitry 120, 175, 300 of FIGS. 1, 2, 3, and 4. The mismatch compensation circuitry 530 generates the plus and minus compensation currents to compensate the plus and minus side input voltages of the first amplifier 510.

The common mode determination circuitry 535 has a first input coupled to the first amplifier 510, the first resistor 515, and the current compensation circuitry 550 and may be coupled to the IDAC 150. The common mode determination circuitry 535 has a second input coupled to the first amplifier 510, the second resistor 525, and the current compensation circuitry 550 and may be coupled to the IDAC 150. The common mode determination circuitry 535 receives the plus and minus input voltages of the first amplifier 510. The common mode determination circuitry 535 is another example implementation of the common mode determination circuitry 250, 305, 470 of FIGS. 2, 3, and 4. The common mode determination circuitry 535 determines a common mode voltage of the plus and minus input voltages. The common mode determination circuitry 535 supplies the common mode voltage to the second amplifier 540.

The second amplifier 540 has a first input coupled to the common mode determination circuitry 535 and a second input coupled to the common mode reference voltage 545. The second amplifier 540 has an output coupled to the current compensation circuitry 550. The second amplifier 540 receives the common mode voltage from the common mode determination circuitry 535. The second amplifier 540 is another example implementation of the amplifiers 255, 320, 475 of FIGS. 2, 3, and 4. The second amplifier 540 determines a common mode error voltage responsive to differences between the common mode voltage and the common mode reference voltage 545. The common mode reference voltage 545 is another example of the reference common mode voltages 260, 325, 480 of FIGS. 2, 3, and 4. The second amplifier 540 supplies the common mode error voltage to the current compensation circuitry 550.

The current compensation circuitry 550 has a first input coupled to the second amplifier 540. In some examples, the current compensation circuitry 550 has a clock input coupled to the clock circuitry 130, which supplies the clock signal. The current compensation circuitry 550 receives the common mode error voltage from the second amplifier 540. The current compensation circuitry 550 is another example implementation of the current compensation circuitry 265, 330, 485 of FIGS. 2, 3, and 4. The current compensation circuitry 550 generates plus and minus side compensation currents responsive to the common mode error voltage. The current compensation circuitry 550 supplies the plus side compensation current to the first input of the first amplifier 510 and the minus side compensation current to the second input of the first amplifier 510. Advantageously, the plus and minus side compensation currents compensate the plus and minus input voltages of the first amplifier 450 for mismatch.

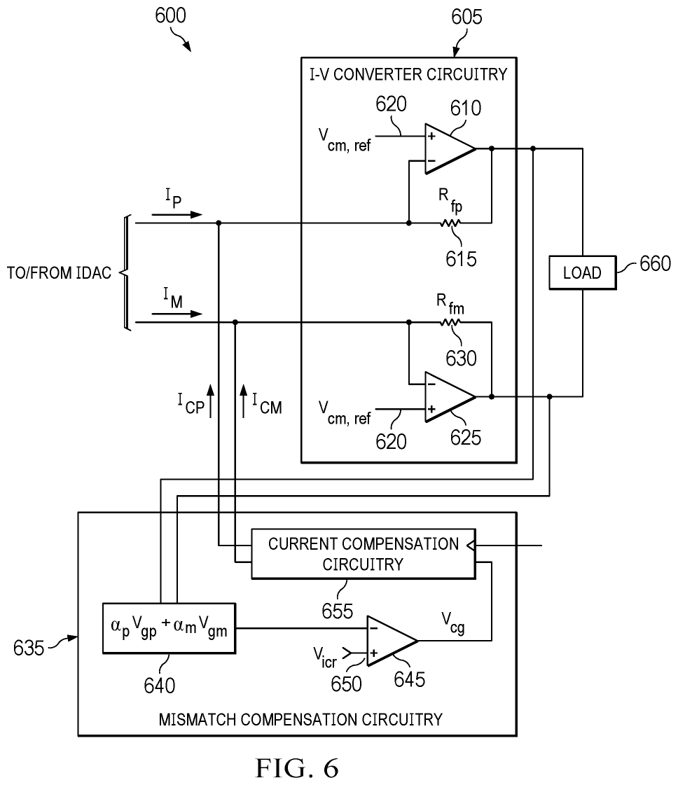

FIG. 6 is a schematic diagram of another example implementation of the mismatch compensation circuitry 120, 175, 300, 530 of FIGS. 1, 2, 3, 4, and 5 in another example DAC 600. In the example of FIG. 6, the DAC 600 includes example current-to-voltage (I-V) converter circuitry 605, example mismatch compensation circuitry 635, and an example load 660. In the example of FIG. 6, the I-V converter circuitry 605 includes a first example amplifier 610, a first example resistor 615, a reference input common mode voltage 620, and a second example amplifier 625, and a second example resistor 630. In the example of FIG. 6, the mismatch compensation circuitry 635 includes example common mode determination circuitry 640, a third example amplifier 645, a reference common mode voltage 650, and example current compensation circuitry 655. The DAC 600 is an example implementation of the DAC 140 of FIGS. 1 and 4, but that has two single ended amplifiers (e.g., the amplifiers 610, 625) to supply a differential analog output signal to the load 660. Also, the DAC 600 may include one or more components of the DAC 140 that are not illustrated (for simplicity). For example, the DAC 600 includes the delta-sigma modulator circuitry 145 of FIGS. 1 and 4, the IDAC 150 of FIGS. 1 and 4, and the unit cells 155, 160, 165 of FIGS. 1 and 4.

The I-V converter circuitry 605 has first and second inputs coupled to the mismatch compensation circuitry 635 and that may be coupled to the IDAC 150. The I-V converter circuitry 605 has first and second outputs coupled to the mismatch compensation circuitry 635 and the load 660. In the example of FIG. 6, the I-V converter circuitry 605 includes the amplifiers 610, 625, the resistors 615, 630, and the reference input common mode voltage 620. The I-V converter circuitry 605 receives the plus and minus side currents from the IDAC 150 and the plus and minus side compensation currents from the mismatch compensation circuitry 635. The I-V converter circuitry 605 is an example implementation of the I-V converter circuitry 170 of FIGS. 1 and 4. Unlike the I-V converter circuitry 170, the I-V converter circuitry 605 of FIG. 5 uses single ended amplifiers to convert the differential pair of input currents into the differential pair of output voltages. The I-V converter circuitry 605 supplies the differential pair of analog output signals to an example load.

The first amplifier 610 has a first input coupled to the first resistor 615, the mismatch compensation circuitry 635, and the current compensation circuitry 655, and may be coupled to the IDAC 150. The first amplifier 610 has a second input coupled to the input common mode voltage 620. The first amplifier 610 has an output coupled to the first resistor 615, the mismatch compensation circuitry 635, the common mode determination circuitry 640, and the load 660.

The first resistor 615 has a first terminal coupled to the first amplifier 610, the mismatch compensation circuitry 635, and the current compensation circuitry 655 and may be coupled to the IDAC 150. The first resistor 615 has a second terminal coupled to the first amplifier 610, the mismatch compensation circuitry 635, the common mode determination circuitry 640, and the load 660.

The amplifiers 610, 625 receive the reference input common mode voltage 620. The reference input common mode voltage 620 represents a desired input mode voltage of the amplifiers 610, 625. In some examples, the reference input common mode voltage 620 is a voltage source.

The second amplifier 625 has a first input that receives the reference input common mode voltage 620. The second amplifier 625 has a second input coupled to the second resistor 630, the mismatch compensation circuitry 635, and the current compensation circuitry 655, and may be coupled to the IDAC 150. The second amplifier 625 has an output coupled to the second resistor 630, the mismatch compensation circuitry 635, the common mode determination circuitry 640, and the load 660.

The second resistor 630 has a first terminal coupled to the second amplifier 625, the mismatch compensation circuitry 635, and the current compensation circuitry 655 and may be coupled to the IDAC 150. The second resistor 525 has a second terminal coupled to the second amplifier 625, the mismatch compensation circuitry 635, the common mode determination circuitry 640, and the load 660.

The mismatch compensation circuitry 635 is coupled to the I-V converter circuitry 605, the amplifiers 610, 625, and the resistors 615, 630 and may be coupled to the IDAC 150 and/or the load 660. In the example of FIG. 6, the mismatch compensation circuitry 635 includes the common mode determination circuitry 640, the third amplifier 645, the reference common mode voltage 650, and the current compensation circuitry 655. The mismatch compensation circuitry 635 of FIG. 6 is another example implementation of the mismatch compensation circuitry 120, 175, 300, 530 of FIGS. 1, 2, 3, 4, and 5. The mismatch compensation circuitry 635 generates the plus and minus compensation currents to compensate the plus and minus side input voltages of the amplifiers 610, 625.

The common mode determination circuitry 640 has a first input coupled to the first amplifier 610 and the first resistor 515 and may be coupled to the load 660. The common mode determination circuitry 640 has a second input coupled to the second amplifier 625 and the second resistor 630 and may be coupled to the IDAC 150. The common mode determination circuitry 640 receives output voltages of the amplifiers 610, 625. The common mode determination circuitry 640 is another example implementation of the common mode determination circuitry 250, 305, 470, 535 of FIGS. 2, 3, 4, and 5. The common mode determination circuitry 640 determines a common mode voltage of the output voltages of the amplifiers 610, 625. The common mode determination circuitry 640 supplies the common mode voltage to the third amplifier 645.

The third amplifier 645 has a first input coupled to the common mode determination circuitry 640 and a second input that receives the common mode reference voltage 650. The third amplifier 645 has an output coupled to the current compensation circuitry 655. The third amplifier 645 receives the common mode voltage from the common mode determination circuitry 640. The third amplifier 645 is another example implementation of the amplifiers 255, 320, 475, 540 of FIGS. 2, 3, 4, and 5. The third amplifier 645 determines a common mode error voltage responsive to differences between the common mode voltage and the common mode reference voltage 650. The common mode reference voltage 650 is another example of the reference common mode voltages 260, 325, 480, 545 of FIGS. 2, 3, 4, and 5. The third amplifier 645 supplies the common mode error voltage to the current compensation circuitry 655.

The current compensation circuitry 655 has a first input coupled to the third amplifier 645. In some examples, the current compensation circuitry 655 has a second input coupled to the clock circuitry 130, which supplies the clock signal. The current compensation circuitry 655 receives the common mode error voltage from the third amplifier 645. The current compensation circuitry 655 is another example implementation of the current compensation circuitry 265, 330, 485, 550 of FIGS. 2, 3, 4, and 5. The current compensation circuitry 655 generates plus and minus side compensation currents responsive to the common mode error voltage. The current compensation circuitry 655 supplies the plus side compensation current to the first input of the first amplifier 610 and the minus side compensation current to the first input of the second amplifier 625. Advantageously, the plus and minus side compensation currents compensate the plus and minus input voltages of the first amplifier 450 for mismatch.

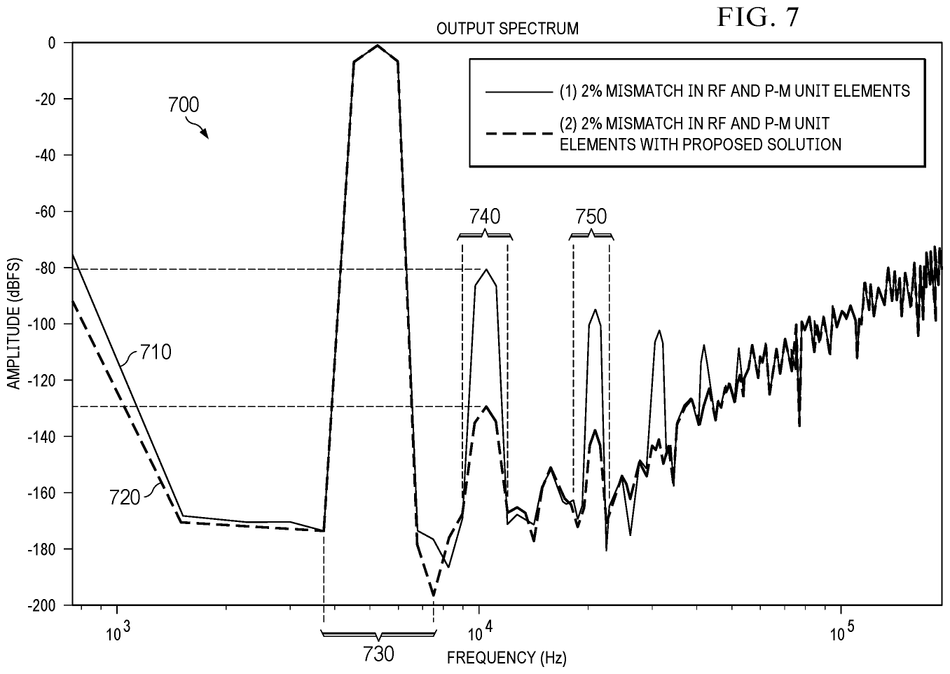

FIG. 7 is a plot 700 of an example operation of the DAC 140 of FIGS. 1 and 4 across a range of frequencies. In the example of FIG. 7, the plot 700 includes an example mismatch plot 710 and an example compensated plot 720. The mismatch plot 710 illustrates signal to noise and/or distortion ratio (SNDR) amplitudes of outputs of the DAC 140 responsive to audio signals of a wide range of frequencies, without the mismatch compensation circuitry 175 of FIGS. 1 and 4. The compensated plot 720 illustrates sound to noise ratio amplitudes of output of the DAC 140 responsive to audio signals of the wide range of frequencies, with the mismatch compensation circuitry 175.

During fundamental frequencies 730, the amplitudes of the plots 710, 720 have a harmonic distortion that is approximately equal, responsive to relatively high amplitudes of audible sound decreasing the sound to noise ratio. During a second harmonic 740, the compensated plot 720 has a lower amplitude compared to the mismatch plot 710. At the second harmonic 740, the signal to noise and/or distortion ratio amplitude of the mismatch plot 710 is approximately eighty decibels (dB), and the signal to noise and/or distortion ratio amplitude of the compensated plot 720 is approximately one-hundred and thirty decibels. Advantageously, the harmonic distortion of the compensated plot 720 is less than the harmonic distortion of the mismatch plot 710 at the second harmonic 740.

During a third harmonic 750, the compensated plot 720 continues to have a lower sound to noise ration amplitude compared to the mismatch plot 710. Advantageously, the mismatch compensation circuitry 175 decreases the harmonic distortion of the DAC 140. Following the third harmonic 750, the amplitudes of the compensated plot 720 begin to linearly increase. However, the signal to noise and/or distortion ratio amplitudes of the mismatch plot 710 continues to spike for subsequent harmonics. Such spikes in the mismatch plot 710 increase total harmonic distortion. Advantageously, the mismatch compensation circuitry 175 decreases the total harmonic distortion of outputs of the DAC 140 by compensating any mismatch between components.

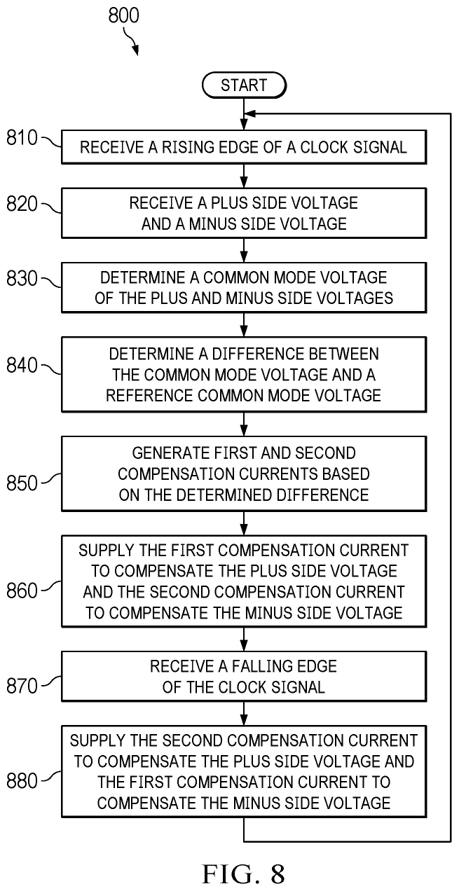

FIG. 8 is a flowchart representative of example operations 800 that may be executed, instantiated, and/or performed using an example implementation of the mismatch compensation circuitry 120, 175, 300, 530, 635 of FIGS. 1, 2, 3, 4, 5, and 6. The example operations 800 begin at Block 810 at which, the IDAC 150 of FIGS. 1 and 4 receives a rising edge of a clock signal. (Block 810). In some examples, the IDAC 150 modifies the logic states of the unit cells 155, 160, 165 of FIGS. 1 and 4 responsive to a rising edge of the clock signal from the clock circuitry 130 of FIG. 1. In such examples, the IDAC 150 updates the plus and minus side currents to reflect a new value responsive to rising edges of the clock signal.

The common mode determination circuitry 250, 305, 470, 535, 640 of FIGS. 2, 3, 4, 5, and 6 receive a plus side voltage and a minus side voltage. (Block 820). In some examples, the plus and minus side voltages represent input voltages of the amplifiers 210, 450, 510 of FIGS. 2, 4, and 5 that are responsive to a differential pair of input currents. In other examples, the plus and minus side voltage represent output voltage of the amplifiers 610, 625 of FIG. 6 that form a differential pair of analog output signals.

The common mode determination circuitry 250, 305, 470, 535, 640 determine a common mode voltage of the plus and minus side voltages. (Block 830). In some examples, the common mode determination circuitry 250, 305, 470, 535, 640 use voltage divider circuitry to determine the common mode voltage of the plus and minus voltages. For example, the common mode determination circuitry 305 includes the resistors 310, 315 of FIG. 3 to determine the common mode voltage. In such examples, the resistors 310, 315 determine the common mode voltage to be a voltage approximately halfway between the plus and minus side voltages.

The amplifies 255, 320, 475, 540, 645 of FIGS. 2, 3, 4, 5, and 6 determine a difference between the common mode voltage and a reference common mode voltage. (Block 840). In some examples, the amplifiers 255, 320, 475, 540, 645 compare the common mode voltage from the common mode determination circuitry 250, 305, 470, 535, 640 to the reference common mode voltages 260, 325, 480, 545, 650 of FIGS. 2, 3, 4, 5, and 6 to determine the common mode error voltage.

The current compensation circuitry 265, 330, 485, 550, 655 of FIGS. 2, 3, 4, 5, and 6 generate first and second compensation currents responsive to the determined difference. (Block 850). In some examples, the current compensation circuitry 265, 330, 485, 550, 655 convert voltages of the common mode error voltage from the amplifiers 255, 320, 475, 540, 645 into the first and second compensation currents. For example, the current compensation circuitry 330 includes the resistors 335, 355 of FIG. 3 to convert the common mode error voltage into the first and second compensation currents.

The current compensation circuitry 265, 330, 485, 550, 655 supply the first compensation current to compensate the plus side voltage and the second compensation current to compensate the minus voltage. (Block 860). In some examples, during a first half of a cycle of the clock signal from the clock circuitry 130, the current compensation circuitry 265, 330, 485, 550, 655 supply the first compensation current as the plus side compensation current and the second compensation current as the minus side compensation current. In such examples, the first compensation current modifies the plus side voltage to correct for mismatch variations and the second compensation current modifies the minus side voltage to correct for mismatch variations.

The current compensation circuitry 265, 330, 485, 550, 655 receives a falling edge of the clock signal. (Block 870). In some examples, the current compensation circuitry 265, 330, 485, 550, 655 receive the clock signal from the clock circuitry 130. In such examples, the clock signal controls switching circuitry, which configures which of the first or second compensation currents are supplied to what side of the amplifiers 255, 320, 475, 540, 645. For example, the current compensation circuitry 330 uses the clock signal to control the transistors 340, 345, 360, 365 of FIG. 3. In such examples, the clock signal controls which of the compensation currents the transistors 340, 345, 360, 365 supply to each side responsive to rising and falling edges of the clock signal.

The current compensation circuitry 265, 330, 485, 550, 655 supply the second compensation current to compensate the plus side voltage and the first compensation current to compensate the minus side voltage. (Block 880). In some examples, during a second half of a cycle of the clock signal from the clock circuitry 130, the current compensation circuitry 265, 330, 485, 550, 655 supply the second compensation current as the plus side compensation current and the first compensation current as the minus side compensation current. In such examples, the first compensation current modifies the minus side voltage to correct for mismatch variations when the second compensation current modifies the plus side voltage to correct for mismatch variations. Advantageously, switching the supply of the first and second compensation currents between sides of the amplifiers 255, 320, 475, 540, 645 reduces an impact of mismatch between components of the current compensation circuitry 265, 330, 485, 550, 655.

Although example methods are described with reference to the flowchart illustrated in FIG. 8, many other methods of implementing the mismatch compensation circuitry 120, 175, 300, 530, 635 of FIGS. 1, 2, 3, 4, 5, and 6 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

As used herein, “approximately” and “about” modify their subjects/values to recognize the potential presence of variations that occur in real world applications. For example, “approximately” and “about” may modify dimensions that may not be exact due to manufacturing tolerances and/or other real-world imperfections as will be understood by persons of ordinary skill in the art. For example, “approximately” and “about” may indicate such dimensions may be within a tolerance range of +/−10% unless otherwise specified herein.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first,” “second,” “third,” etc. are used merely to distinguish between elements of substantially the same type in terms of structure and/or function. These identifiers as used in the detailed description do not necessarily align with those used in the claims.

A device that is “configured to” perform a task or function ma may unit cells 160, 165 y be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
an impedance circuit having a first terminal and a second terminal;
a first amplifier having a first input, a second input, and an output, the first input of the first amplifier coupled to the first terminal of the impedance circuit, the output of the first amplifier coupled to the second terminal of the impedance circuit; and
mismatch compensation circuitry including:
voltage divider circuitry having a first terminal, a second terminal, and a third terminal, the first terminal of the voltage divider circuitry coupled to the second input of the first amplifier, the second terminal of the voltage divider circuitry coupled to the first terminal of the impedance circuit and the first input of the first amplifier;
a second amplifier having an first input and an output, the first input of the second amplifier coupled to the third terminal of the voltage divider circuitry; and
current compensation circuitry having a first terminal, a second terminal and a third terminal, the first terminal of the current compensation circuitry coupled to the output of the second amplifier, the second terminal of the current compensation circuitry coupled to the second input of the first amplifier, the third terminal of the current compensation circuitry coupled to the second input of the first amplifier.

2. The apparatus of claim 1, wherein the impedance circuit is a first impedance circuit, the output of the first amplifier is a first output, the apparatus further comprising a second impedance circuit having a first terminal and a second terminal, the first terminal of the second impedance circuit coupled to the second input of the first amplifier, the second terminal of the second impedance circuit coupled to a second output of the first amplifier.

3. The apparatus of claim 1, further comprising an current digital-to-analog converter comprising:
first unit cell circuitry having a first terminal and a second terminal, the first terminal of the first unit cell circuitry coupled to the second input of the first amplifier and the second terminal of the current compensation circuitry, the second terminal of the first unit cell circuitry coupled to the first input of the first amplifier and the third terminal of the current compensation circuitry; and
second unit cell circuitry having a first terminal and a second terminal, the first terminal of the second unit cell circuitry coupled to the second input of the first amplifier, the second terminal of the current compensation circuitry, and the first terminal of the first unit cell circuitry, the second terminal of the second unit cell circuitry coupled to the first input of the first amplifier, the third terminal of the current compensation circuitry, and the second terminal of the first unit cell circuitry.

4. The apparatus of claim 1, wherein the voltage divider circuitry comprising:
a first resistor having a first terminal and a second terminal, the first terminal of the first resistor coupled to the second input of the first amplifier, the second terminal of the first resistor coupled to the first input of the second amplifier; and
a second resistor having a first terminal and a second terminal, the first terminal of the second resistor coupled to the first input of the second amplifier and the second terminal of the first resistor, the second terminal of the second resistor coupled to the first input of the first amplifier.

5. The apparatus of claim 1, wherein the current compensation circuitry comprising:
a first resistor having a first terminal and a second terminal, the first terminal of the first resistor coupled to the output of the second amplifier;
a second resistor having a first terminal and a second terminal, the first terminal of the second resistor coupled to the output of the second amplifier and the first terminal of the first resistor; and
switching circuitry having a first terminal, a second terminal, a third terminal, and a fourth terminal, the first terminal of the switching circuitry coupled to the second terminal of the first resistor, the second terminal of the switching circuitry coupled to the second terminal of the second resistor, the third terminal of the switching circuitry coupled to the second input of the first amplifier, the fourth terminal of the switching circuitry coupled to the first input of the first amplifier.

6. The apparatus of claim 5, wherein the switching circuitry comprising:
a first transistor having a first terminal, a second terminal, and a control terminal, the first terminal of the first transistor coupled to the second terminal of the first resistor, the second terminal of the first transistor coupled to the second input of the first amplifier, and the control terminal of the first transistor adaptive to be coupled to a clock input; and
a second transistor having a first terminal, a second terminal, and a control terminal, the first terminal of the second transistor coupled to the second terminal of the first resistor and the first terminal of the first transistor, the second terminal of the second transistor coupled to the second input of the first amplifier and the second terminal of the first transistor, and the control terminal of the second transistor adaptive to be coupled to an inverted clock signal, wherein the inverted clock signal is a logic NOT of the clock input.

7. The apparatus of claim 1, wherein the apparatus is converter circuitry configured to perform one of a digital-to-analog conversion or an analog-to-digital conversion.

8. A system comprising:
voltage divider circuitry configured to determine a common mode voltage of a differential pair of signals having a first voltage and a second voltage;
a first amplifier coupled to the voltage divider circuitry, the first amplifier configured to determine a difference between the common mode voltage and a reference common mode voltage;
current compensation circuitry coupled to the first amplifier, the current compensation circuitry configured to generate a first current and a second current responsive to the difference between voltages; and
a second amplifier coupled to the voltage divider circuitry and the current compensation circuitry, the second amplifier to compensate the first voltage with the first current and the second voltage with the second current.

9. The system of claim 8, wherein the first amplifier has an input, the second amplifier has a first input and a second input, voltage divider circuitry comprising:
a first resistor having a first terminal and a second terminal, the first terminal of the first resistor coupled to the first input of the second amplifier; and
a second resistor having a first terminal and a second terminal, the first terminal of the second resistor coupled to the second input of the second amplifier, the second terminal of the second resistor coupled to the input of the first amplifier and the second terminal of the first resistor.

10. The system of claim 8, wherein the first amplifier has a first input, a second input, and an output, the first input of the first amplifier coupled to the voltage divider circuitry, the second input of the first amplifier coupled to the reference common mode voltage, the output of the first amplifier coupled to the current compensation circuitry.

11. The system of claim 8, the voltage divider circuitry having a first input and a second input, the first amplifier having an output, the second amplifier having a first input and a second input, the current compensation circuitry comprising:
a first resistor having a first terminal and a second terminal;
a second resistor having a first terminal and a second terminal, the first terminal of the second resistor coupled to the output of the first amplifier and the first terminal of the first resistor; and
switching circuitry having a first input, a second input, a first output, and a second output, the first input of the switching circuitry coupled to the second terminal of the first resistor, the second input of the switching circuitry coupled to the second terminal of the second resistor, the first output of the switching circuitry coupled to the first input of the second amplifier, the second output of the switching circuitry coupled to the second input of the second amplifier.

12. The system of claim 11, the switching circuitry to couple the first resistor to the first output of the switching circuitry and the second resistor to the second output of the switching circuitry for a first half of a clock cycle, and the switching circuitry to couple the first resistor to the second output of the switching circuitry and the second resistor to the first output of the switching circuitry for a second half of the clock cycle.

13. The system of claim 8, the voltage divider circuitry having a first input and a second input, the current compensation circuitry having a first output and a second output, the second amplifier having a first input and a second input, the first input of the second amplifier coupled to the first input of the voltage divider circuitry and the first output of the current compensation circuitry, the second input of the second amplifier coupled to the second input of the voltage divider circuitry and the second output of the current compensation circuitry.

14. The system of claim 8, wherein the system is converter circuitry to perform one of a digital-to-analog conversion or an analog-to-digital conversion.

15. A method comprising:
determining a common mode voltage of a differential pair of signals having a first voltage and a second voltage;
determining a difference between the common mode voltage and a reference common mode voltage;
generating a first current and a second current responsive to the difference between voltages; and
compensating the first voltage with the first current and the second voltage with the second current.

16. The method of claim 15, wherein the compensating the first voltage with the first current and the second voltage with the second current is for a first half of a cycle of a clock, the method further comprising compensating the first voltage with the second current and the second voltage with the first current for a second half of the cycle of the clock.

17. The method of claim 15, further comprising determining an update of converter circuitry, the update to set the common mode voltage by setting the first voltage at a first input of an amplifier and the second voltage at a second input of the amplifier.

18. The method of claim 15, further comprising determining the common mode voltage to be approximately a midpoint between the first voltage and the second voltage, the first current and the second current to correct the common mode voltage based on the reference common mode voltage.

19. The method of claim 15, further comprising setting the common mode voltage of the differential pair of signals to be approximately equal to the reference common mode voltage responsive to compensating the first voltage and the second voltage.

20. The method of claim 15, wherein the compensating the first voltage and the second voltage corrects mismatch between first and second inputs of an amplifier.
